(19) United States
(12) Patent Application Publication
(10) Pub. No.: US 2026/0157095 A1
(43) Pub. Date: Jun. 4, 2026

(54) DISPLAY DEVICE AND ELECTRONIC DEVICE INCLUDING THE SAME

(71) Applicant: Samsung Display Co., Ltd., Yongin-si (KR)

(72) Inventors: Go Een JEONG, Yongin-si (KR); Kwang Soo BAE, Yongin-si (KR); Seo Young LIM, Yongin-si (KR); Soo Yeong HONG, Yongin-si (KR)

(73) Assignee: Samsung Display Co., Ltd., Yongin-si (KR)

(21) Appl. No.: 19/335,339

(22) Filed: Sep. 22, 2025

(30) Foreign Application Priority Data
Nov. 29, 2024 (KR) 10-2024-0175051

(51) Int. Cl. H10K 59/80

(52) U.S. Cl. CPC H10K 59/8792; H10K 59/879

(57) ABSTRACT

A display device includes a first light blocking layer on the element layer and defining a first hole overlapping a light emitting element and a second hole overlapping a light receiving element, a second light blocking layer on the first light blocking layer and defining a first transmission hole overlapping the first hole and a second transmission hole overlapping the second hole, a third light blocking layer on the second light blocking layer and defining a third transmission hole overlapping the first transmission hole and a fourth transmission hole overlapping the second transmission hole, a first lens in the first transmission hole, a second lens in the second transmission hole, a third lens in the third transmission hole, and a fourth lens in the fourth transmission hole. The first lens, the third lens, and the fourth lens include condensing lenses, and the second lens includes a collimating lens.

### CROSS-REFERENCE TO RELATED APPLICATION

This application claims priority from Korean Patent Application No. 10-2024-0175051 filed on Nov. 29, 2024, in the Korean Intellectual Property Office, and all the benefits accruing therefrom under 35 U.S.C. § 119, the contents of which in its entirety are incorporated herein by reference.

### BACKGROUND

Some example embodiments relate to a display device and/or an electronic device including the same.

With the advance of information-oriented society, more and more demands are placed on display devices for displaying images in various ways. For example, display devices are employed in various electronic devices such as smartphones, digital cameras, laptop computers, navigation devices, and/or smart televisions.

The display device may be or may include a flat panel display device such as one or more of a liquid crystal display device, a field emission display device and an organic light emitting display device. Among the flat panel display devices, in the light emitting display device, since each of pixels of a display panel includes a light emitting element capable of emitting light by itself, an image can be displayed without a backlight unit providing light to the display panel.

### SUMMARY

Some example embodiments may provide a display device that increases the amount of light received by a light receiving element, and/or an electronic device including the same.

Alternatively or additionally, some example embodiments may provide a display device with improved sensing accuracy, and/or an electronic device including the same.

However, aspects of example embodiments are not restricted to those set forth herein. The above and other aspects of example embodiments will become more apparent to one of ordinary skill in the art to example embodiments pertain by referencing the detailed description given below.

According to some example embodiments, there is provided a display device including, a substrate, an element layer on the substrate and including a light emitting element and a light receiving element spaced apart from each other, a first light blocking layer on the element layer and defining a first hole overlapping the light emitting element and a second hole overlapping the light receiving element, a second light blocking layer on the first light blocking layer and defining a first transmission hole overlapping the first hole and a second transmission hole overlapping the second hole, a third light blocking layer on the second light blocking layer and defining a third transmission hole overlapping the first transmission hole and a fourth transmission hole overlapping the second transmission hole, and a lens unit including a first lens in the first transmission hole, a second lens in the second transmission hole, a third lens in the third transmission hole, and a fourth lens in the fourth transmission hole. The first lens, the third lens, and the fourth lens include condensing lenses, and the second lens includes a collimating lens.

In some example embodiments, the first lens, the third lens, and the fourth lens comprise convex lenses.

In some example embodiments, the first lens and the third lens have convex surfaces in an opposite direction to a side where the light emitting element is located.

In some example embodiments, the fourth lens has a convex surface toward a side where the light emitting element is located.

In some example embodiments, the third lens comprises a concave lens.

In some example embodiments, the third lens has a concave surface with respect to a side where the light receiving element is located.

In some example embodiments, the display device may further comprise, a first passivation layer disposed between the first light blocking layer and the second light blocking layer, a second passivation layer disposed between the second light blocking layer and the third light blocking layer, and an overcoat layer disposed on the third light blocking layer.

In some example embodiments, a refractive index of the lens unit is greater than or equal to those of the first passivation layer, the second passivation layer, and the overcoat layer.

In some example embodiments, a refractive index of the overcoat layer is greater than or equal to that of the second passivation layer, and a refractive index of the second passivation layer is greater than or equal to that of the first passivation layer.

In some example embodiments, at least one of the first passivation layer, the second passivation layer, and the overcoat layer contain an organic material.

In some example embodiments, the lens unit contains at least one of silicon, polymethyl methacrylate, or plastic.

In some example embodiments, the display device may further comprise a color filter overlapping the first hole.

In some example embodiments, the color filter does not overlap the second hole.

Alternatively or additionally according to some example embodiments, there is provided a display device including a substrate including a display area in which a first pixel and a second pixel are arranged, a light emitting element and a light receiving element spaced apart from each other in the display area, a first light blocking layer defining a first hole in the first pixel and overlapping the light emitting element, a second hole in the first pixel and overlapping the light receiving element, a third hole in the second pixel and overlapping the light emitting element, and a fourth hole in the second pixel and overlapping the light receiving element, a second light blocking layer defining a first transmission hole in the second pixel and overlapping the third hole and a second transmission hole in the second pixel and overlapping the fourth hole, a third light blocking layer defining a third transmission hole overlapping the first transmission hole and a fourth transmission hole overlapping the second transmission hole, and a lens unit including a first lens in the first transmission hole, a second lens disposed in the second transmission hole, a third lens in the third transmission hole, and a fourth lens in the fourth transmission hole. The first lens, the third lens, and the fourth lens include condensing lenses, and the second lens includes a collimating lens.

In some example embodiments, the first lens, the third lens, and the fourth lens comprise convex lenses.

In some example embodiments, the third lens comprises a concave lens.

In some example embodiments, the second light blocking layer and the third light blocking layer are not disposed in the first pixel.

In some example embodiments, the lens unit is not in the first pixel.

In some example embodiments, the first to fourth transmission holes do not overlap the first hole and the second hole.

Alternatively or additionally according to some example embodiments, there is provided an electronic device including a display device, the display device including a substrate, an element layer on the substrate and including a light emitting element and a light receiving element spaced apart from each other, a first light blocking layer on the element layer and defining a first hole overlapping the light emitting element and a second hole overlapping the light receiving element, a second light blocking layer disposed on the first light blocking layer and defining a first transmission hole overlapping the first hole and a second transmission hole overlapping the second hole, a third light blocking layer on the second light blocking layer and defining a third transmission hole overlapping the first transmission hole and a fourth transmission hole overlapping the second transmission hole, and a lens unit including a first lens in the first transmission hole, a second lens in the second transmission hole, a third lens in the third transmission hole, and a fourth lens disposed in the fourth transmission hole. The first lens, the third lens, and the fourth lens include condensing lenses, and the second lens includes a collimating lens.

In accordance with the display device and/or the electronic device including the same according to at least one example embodiment, it may be possible to increase the amount of light received by the light receiving element.

Alternatively or additionally in accordance with the display device and/or the electronic device including the same according to at least one example one embodiment, it may be possible to improve the sensing accuracy.

It should be noted that effects of some example embodiments are not limited to those described above and other effects will be apparent to those of ordinary skill in the art from the following descriptions.

### BRIEF DESCRIPTION OF THE DRAWINGS

The above and other aspects and features of inventive concepts will become more apparent by describing in detail some example embodiments thereof with reference to the attached drawings, in which:

FIG. 1 is a schematic perspective view showing an electronic device according to some example embodiments;

FIG. 2 is a perspective view illustrating a display device included in an electronic device according to some example embodiments;

FIG. 3 is a cross-sectional view illustrating a display device according to some example embodiments;

FIG. 4 is a plan view illustrating a light emitting pixel, a sensing pixel, various drivers, and various wires of a display device according to some example embodiments;

FIG. 5 is a block diagram illustrating a light emitting pixel, a sensing pixel, various drivers, and various wires of a display device according to some example embodiments;

FIG. 6 is a circuit diagram illustrating a light emitting pixel of a display device according to some example embodiments;

FIG. 7 is a cross-sectional view illustrating a light emitting pixel of a display device according to some example embodiments;

FIG. 8 is a circuit diagram of a sensing pixel of a display device according to some example embodiments;

FIG. 9 is a cross-sectional view illustrating a sensing pixel of a display device according to some example embodiments;

FIG. 10 is a plan view illustrating an emission area and a sensing area in a display device according to some example embodiments;

FIG. 11 is a schematic diagram illustrating pixel types according to an emission mode of the display device according to some example embodiments;

FIG. 12 is a plan view illustrating an emission area, a sensing area, and a first light blocking layer in a display device according to some example embodiments;

FIG. 13 is a plan view illustrating an emission area, a sensing area, and a color filter layer in a display device according to some example embodiments;

FIG. 14 is a plan view illustrating an emission area, a sensing area, and a second light blocking layer in a display device according to some example embodiments;

FIG. 15 is a plan view illustrating an emission area, a sensing area, and a third light blocking layer in a display device according to some example embodiments;

FIG. 16 is a cross-sectional view taken along line X1-X1′;

FIG. 17 is a cross-sectional view taken along line X2-X2′; and

FIG. 18 is a cross-sectional view illustrating a sensing process of a display device according to some example embodiments.

### DETAILED DESCRIPTION

Inventive concepts will now be described more fully hereinafter with reference to the accompanying drawings, in which some example embodiments are shown. Inventive concepts may, however, be embodied in different forms and should not be construed as limited to the example embodiments set forth herein. Rather, these example embodiments are provided so that this disclosure will be thorough and complete, and will filly convey the scope of the invention to those of ordinary skill in the art.

It will also be understood that when a layer is referred to as being “on” another layer or substrate, it can be directly on the other layer or substrate, or intervening layers may also be present. The same reference numbers indicate the same components throughout the specification.

Hereinafter, some example embodiments will be described in detail with reference to the accompanying drawings.

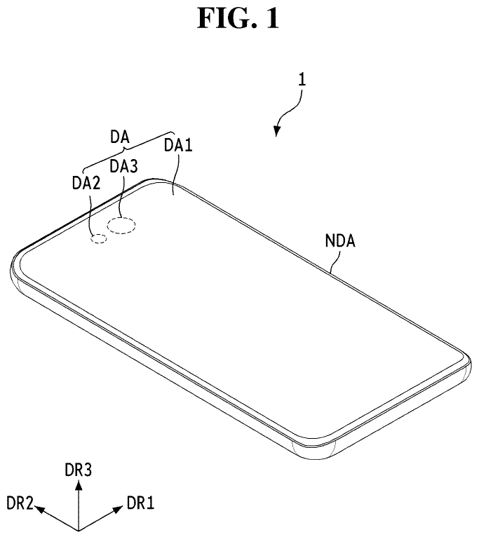

FIG. 1 is a schematic perspective view showing an electronic device according to some example embodiments.

Referring to FIG. 1, an electronic device 1 displays a moving image and/or a still image. The electronic device 1 may refer to any electronic device providing a display screen. Examples of the electronic device 1 may include but are not limited to one or more of a television, a laptop computer, a monitor, a billboard, an Internet-of-Things device, a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation device, a game machine, a digital camera, a camcorder and the like, which provide a display screen.

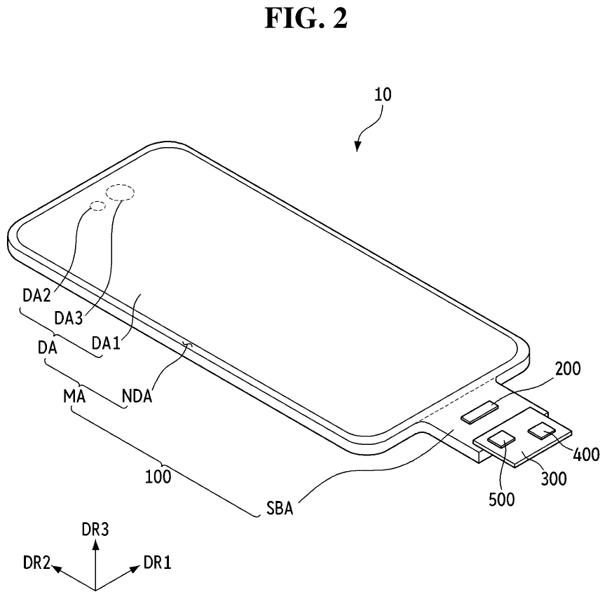

The electronic device 1 may include a display device 10 (see FIG. 2) providing a display screen. Examples of the display device may include but are not limited to one or more of an inorganic light emitting diode display device, an organic light emitting display device, a quantum dot light emitting display device, a plasma display device and a field emission display device. In the following description, a case where an organic light emitting diode display device is applied as a display device will be exemplified, but example embodiments are not limited thereto, and other display devices may be applied within the same scope of technical spirit.

The shape of the electronic device 1 may be variously modified. For example, the electronic device 1 may have a shape such as a rectangular shape elongated in a horizontal direction, a rectangular shape elongated in a vertical direction, a square shape, a quadrilateral shape with or without rounded corners (vertices), other polygonal shapes and/or circular or elliptical shapes. The shape of a display area DA of the electronic device 1 may also be similar to the overall shape of the electronic device 1. FIG. 1 illustrates the electronic device 1 having a rectangular shape in which a length in a second direction DR2 is longer than a length in a first direction DR1; example embodiments are not limited thereto.

In the illustrated figure, the first direction DR1 and the second direction DR2 cross each other as horizontal directions. For example, the first direction DR1 and the second direction DR2 may be orthogonal to each other. In addition, a third direction DR3 crosses the first direction DR1 and the second direction DR2, and may be, for example, perpendicular directions orthogonal to each other. Unless otherwise defined, in the present specification, directions indicated by arrows of the first to third directions DR1, DR2, and DR3 may be referred to as one side, and the opposite directions thereto may be referred to as the other side. Also, the terms “above,” “upper side,” “upper portion,” “top,” and “top surface,” as used herein, refer to a direction indicated by an arrow in the drawing in the third direction DR3 based on the drawings, and the terms “below,” “lower side,” “lower portion,” “bottom,” and “bottom surface,” as used herein, refer to a direction opposite to the direction indicated by the arrow in the third direction DR3 based on the drawings.

The electronic device 1 may include the display area DA and a non-display area NDA. The display area DA may not overlap with the non-display area NDA. The display area DA is or includes an area where a screen can be displayed, and the non-display area NDA is or includes an area where a screen is not displayed. The display area DA may also be referred to as an active region, and the non-display area NDA may also be referred to as a non-active region. The display area DA may substantially occupy the center of the electronic device 1.

The display area DA may include a first display area DA1, a second display area DA2, and a third display area DA3. The second display area DA2 and the third display area DA3 are areas in which components for adding various functions to the electronic device 1 are disposed, and the second display area DA2 and the third display area DA3 may correspond to a component area.

For example, in the second display area DA2 and the third display area DA3, one or more of a camera module for imaging or recognizing an image, a face recognition sensor module for detecting a user's face, a pupil recognition sensor module for detecting a user's pupil, an acceleration sensor module and a geomagnetic sensor module for determining the movement of the display device, a proximity sensor module and an infrared sensor module for detecting whether the front surface of the display device 10 is close, and an illuminance sensor module for measuring a degree of external brightness, and/or the like may be disposed.

FIG. 2 is a perspective view illustrating a display device included in an electronic device according to some example embodiments.

Referring to FIG. 2 in addition to FIG. 1, the electronic device 1 according to some example embodiments may include the display device 10. The display device 10 may provide a screen displayed by the electronic device 1. The display device 10 may have a planar shape similar to the shape of the electronic device 1. For example, the display device 10 may have a shape similar to a rectangular shape having a short side in the first direction DR1 and a long side in the second direction DR2. The edge where the short side in the first direction DR1 and the long side in the second direction DR2 meet may be beveled and/or rounded to have a curvature, but is not limited thereto and may be formed at a right angle. The planar shape of the display device 10 is not limited to a quadrilateral shape, and may be formed in a shape similar to another polygonal shape, a circular shape, or elliptical shape.

The display device 10 may include a display panel 100, a display driver 200, a circuit board 300, a touch driver 400, and a power supply unit 500.

The display panel 100 may include a main region MA and a sub-region SBA.

The main region MA may include the display area DA including pixels displaying an image and the non-display area NDA disposed around the display area DA. The display area DA may be disposed in the center of the main region MA, and the non-display area NDA may surround the display area DA. The display area DA may include the first display area DA1, the second display area DA2, and the third display area DA3. The display area DA may emit light from a plurality of emission areas and/or from a plurality of opening areas. For example, the display panel 100 may include a pixel circuit including switching elements, a pixel defining film defining an emission area or an opening area, and a self-light emitting element.

For example, the self-light emitting element may include at least one of an organic light emitting diode (LED) including an organic light emitting layer, a quantum dot LED including a quantum dot light emitting layer, an inorganic LED including an inorganic semiconductor, or a micro LED, but is not limited thereto.

The non-display area NDA may be or may correspond to an area outside the display area DA. The non-display area NDA may be defined as an edge area of the main region MA of the display panel 100. The non-display area NDA may include one or more of a gate driver (not illustrated) that supplies gate signals to the gate lines, and fan-out lines (not illustrated) that connect the display driver 200 to the display area DA.

The sub-region SBA may be or may correspond to a region extending from one side of the main region MA. The sub-region SBA may include a flexible material which can be bent, folded, and/or rolled. For example, when the sub-region SBA is bent, the sub-region SBA may overlap the main region MA in a thickness direction (e.g., the third direction DR3). The sub-region SBA may include the display driver 200 and a pad portion connected to the circuit board 300. In some example embodiments, the sub-region SBA may be omitted, and the display driver 200 and the pad portion may be disposed in the non-display area NDA.

The display driver 200 may output signals and/or voltages for driving the display panel 100. The display driver 200 may supply data voltages to data lines. The display driver 200 may supply a power voltage to the power line and may supply a gate control signal to the gate driver. The display driver 200 may be formed as an integrated circuit (IC) and mounted on the display panel 100 by a chip on glass (COG) method, a chip on plastic (COP) method, or an ultrasonic bonding method. For example, the display driver 200 may be disposed in the sub-region SBA, and may overlap the main region MA in the thickness direction by bending of the sub-region SBA. In some example embodiments, the display driver 200 may be mounted on the circuit board 300.

The circuit board 300 may be attached to the pad portion of the display panel 100, for example, by using an anisotropic conductive film (ACF). Lead lines of the circuit board 300 may be electrically connected to the pad portion of the display panel 100. The circuit board 300 may be a flexible printed circuit board, a printed circuit board, or a flexible film such as a chip on film.

The touch driver 400 may be mounted on the circuit board 300. The touch driver 400 may be connected to a touch sensing unit of the display panel 100. The touch driver 400 may supply a touch driving signal to a plurality of touch electrodes of the touch sensing unit and may sense an amount of change in capacitance between the plurality of touch electrodes. For example, the touch driving signal may be or may include a pulse signal having a frequency such as but not limited to a predetermined frequency. The touch driver 400 may calculate whether an input is made and input coordinates based on an amount of change in capacitance between the plurality of touch electrodes. The touch driver 400 may be formed as an integrated circuit (IC).

The power supply unit 500 may be disposed on the circuit board 300 to supply a power voltage to the display driver 200 and the display panel 100. The power supply unit 500 may generate a driving voltage to supply it to a driving voltage line, and may generate a common voltage to supply it to a common electrode. For example, the driving voltage may be or may correspond to a high potential voltage for driving the light emitting element, and the common voltage may be or may correspond to a low potential voltage for driving the light emitting element. The power supply unit 500 may generate an initialization voltage to supply it to an initialization voltage line, generate a reference voltage to supply it to a reference voltage line, generate a bias voltage to supply it to a bias voltage line, and generate a reset voltage to supply it to a reset voltage line.

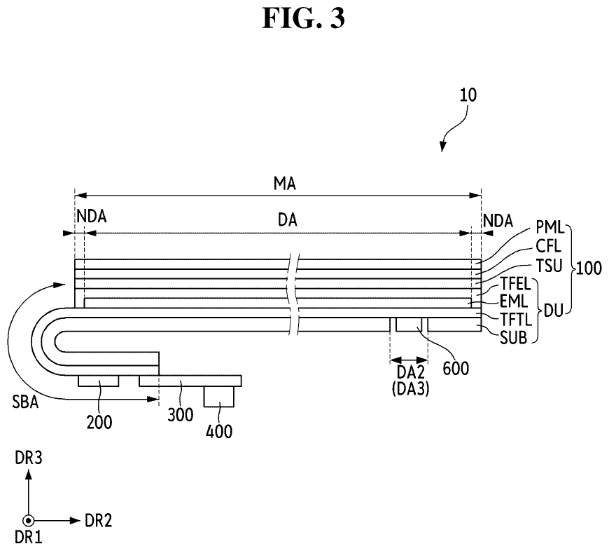

FIG. 3 is a cross-sectional view illustrating a display device according to some example embodiments. FIG. 3 illustrates the sub-region SBA of the display panel 100 in a bent state in the display device 10 of FIG. 2.

Referring to FIG. 3, the display panel 100 may include a display layer DU, a touch sensing layer TSU, a color filter layer CFL, and a light blocking member layer PML. The display layer DU may include a substrate SUB, a transistor layer TFTL, an element layer EML, and an encapsulation layer TFEL.

The substrate SUB may be or may include a base substrate and/or a base member. The substrate SUB may be or may include a flexible substrate which can be bent, folded, and/or rolled. For example, the substrate SUB may include a polymer resin such as polyimide (PI), but is not limited thereto. In some example embodiments, the substrate SUB may include a glass material and/or a metal material.

The transistor layer TFTL may be disposed on the substrate SUB. The transistor layer TFTL may include a plurality of thin-film transistors constituting or included in a light emitting pixel and a sensing pixel of the pixels. The transistor layer TFTL may further include one or more of gate lines, data lines, power lines, gate control lines, fan-out lines that connect the display driver 200 to the data lines, and lead lines that connect the display driver 200 to the pad portion. Each of the thin film transistors may include a semiconductor region, a source electrode, a drain electrode, and a gate electrode. For example, when the gate driver is formed on one side of the non-display area NDA of the display panel 100, the gate driver may include thin film transistors.

The transistor layer TFTL may be disposed in the display area DA, the non-display area NDA, and the sub-region SBA. One or more of thin film transistors, gate lines, data lines, and power lines of the transistor layer TFTL may be disposed in the display area DA. Gate control lines and fan-out lines of the transistor layer TFTL may be disposed in the non-display area NDA. The lead lines of the transistor layer TFTL may be disposed in the sub-region SBA.

The display device 10 according to some example embodiments may be implemented with structural simplicity and/or a reduced manufacturing cost by disposing a light emitting pixel circuit for driving the light emitting element and a sensing pixel circuit for driving a light receiving element together in or at least partly in or on the transistor layer TFTL. For example, the wiring layers and insulating layers included in the transistor layer TFTL may be shared by the light emitting pixel circuit and the sensing pixel circuit, and the wiring formation process of the light emitting pixel circuit and the wiring formation process of the sensing pixel circuit may be performed simultaneously or partially simultaneously or successively. For example, since only the sensing pixel circuit formation process is added to the manufacturing process of the existing display device 10, the manufacturing cost may be reduced, and/or the structure may be simplified by sharing some layers.

The element layer EML may be disposed on the transistor layer TFTL. The element layer EML may include the light emitting element of the light emitting pixel, the light receiving element of the sensing pixel, and the pixel defining film that defines the light emitting pixel and the sensing pixel. The light emitting element may emit light and may be formed of a pixel electrode, a light emitting layer, and a common electrode that are sequentially stacked, and the light receiving element may receive light and may be formed of a sensor electrode, a light receiving layer, and a common electrode sequentially stacked. The light emitting elements and light receiving elements of the element layer EML may be disposed in the display area DA.

For example, the light emitting layer may be or may include an organic light emitting layer including an organic material. The light emitting layer may include a hole transporting layer, an organic light emitting layer, and an electron transporting layer. When the pixel electrode receives a voltage, such as a predetermined voltage, through the transistor of the transistor layer TFTL and the common electrode receives a cathode voltage, holes may move to the organic light emitting layer through the hole transporting layer, electrons may move to the organic light emitting layer through the electron transporting layer, and the holes and the electrons may combine with each other in the organic light emitting layer to emit light. For example, the pixel electrode may be or may correspond to an anode electrode, and the common electrode may be or may correspond to a cathode electrode, but example embodiments are not limited thereto.

For another example, the plurality of light emitting elements may alternatively or additionally include one or more of a quantum dot light emitting diode including a quantum dot light emitting layer, an inorganic light emitting diode including an inorganic semiconductor, or a micro light emitting diode.

The light receiving element may receive light and may convert light energy into an electrical signal. When an object is positioned above the display panel 100, light emitted from the light emitting element may be reflected by the object, and the light receiving element may receive the reflected light. The sensing pixel that has received the light reflected from the object may generate a sensing signal. A main processor may generate sensing data based on the sensing signal, and may determine the shape of the object, the distance to the object, and/or the like, based on the sensing data. For example, the light receiving element may be or may include an organic photodiode, but is not limited thereto.

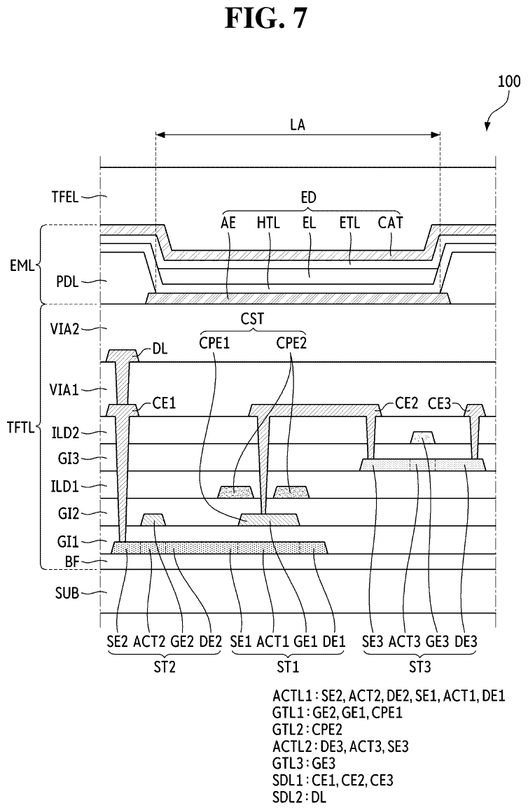

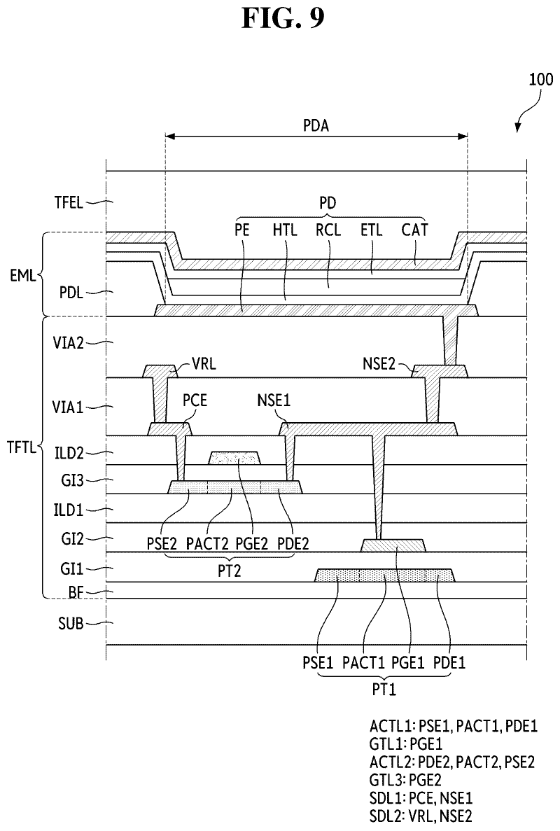

The display device 10 according to some example embodiments may be implemented with structural simplicity and/or reduced manufacturing cost by disposing the light emitting element and the light receiving element together in the element layer EML. For example, a deposition process for forming a light emitting layer EL (see FIG. 7) of the light emitting element and a deposition process for forming a light receiving layer RCL (see FIG. 9) of the light receiving element may be performed simultaneously or at least partly simultaneously or successively. Alternatively or additionally, the light emitting element and the light receiving element may share a hole transporting layer HTL (see FIG. 7), an electron transporting layer ETL (see FIG. 7), and a common electrode CAT (see FIG. 7) to be described later. For example, since only the light receiving element formation process is added to the manufacturing process of an existing display device, the manufacturing cost may be reduced, and/or the structure may be simplified by sharing some layers.

The encapsulation layer TFEL may cover the top surface and the side surface of the element layer EML, and may protect the element layer EML. The encapsulation layer TFEL may include at least one inorganic film and at least one organic film for encapsulating the element layer EML.

The touch sensing layer TSU may be disposed on the encapsulation layer TFEL. The touch sensing layer TSU may include a plurality of touch electrodes for sensing a user's touch in a capacitive manner, and touch lines connecting the plurality of touch electrodes to the touch driver 400. For example, the touch sensing layer TSU may sense the user's touch by using a mutual capacitance method and/or a self-capacitance method.

In some example embodiments, the touch sensing layer TSU may be disposed on a separate substrate disposed on the display layer DU. In this case, the substrate supporting the touch sensing layer TSU may be or may correspond to a base member that encapsulates the display layer DU.

The plurality of touch electrodes of the touch sensing layer TSU may be disposed in a touch sensor area overlapping the display area DA. The touch lines of the touch sensing layer TSU may be disposed in a touch peripheral area that overlaps the non-display area NDA.

The color filter layer CFL may be disposed on the touch sensing layer TSU. The color filter layer CFL may include a plurality of color filters respectively corresponding to the plurality of emission areas. Each of the color filters may selectively transmit light of a specific wavelength and may block and/or absorb light of a different wavelength. The color filter layer CFL may absorb a part of light coming from the outside of the display device 10 to reduce reflected light due to external light. Accordingly, the color filter layer CFL may prevent or reduce the likelihood of and/or impact from color distortion caused by reflection of the external light.

Since the color filter layer CFL is disposed, e.g., is directly disposed on the touch sensing layer TSU, the display device 10 may not require or may not use a separate substrate for the color filter layer CFL. Accordingly, the thickness of the display device 10 may be relatively small.

The light blocking member layer PML may be disposed on the color filter layer CFL. The light blocking member layer PML may include light blocking patterns disposed to correspond to specific pixels of the display layer DU. The display device 10 may further include the light blocking member layer PML to control visibility at a specific viewing angle and provide a privacy protection mode to the user.

In some example embodiments, the display device 10 may further include an optical device 600. The optical device 600 may be disposed in the second display area DA2 or the third display area DA3. The optical device 600 may emit or receive light in infrared, ultraviolet, and visible light bands. For example, the optical device 600 may be an optical sensor that detects light incident on the display device 10 such as one or more of a proximity sensor, an illuminance sensor, and a camera sensor or an image sensor.

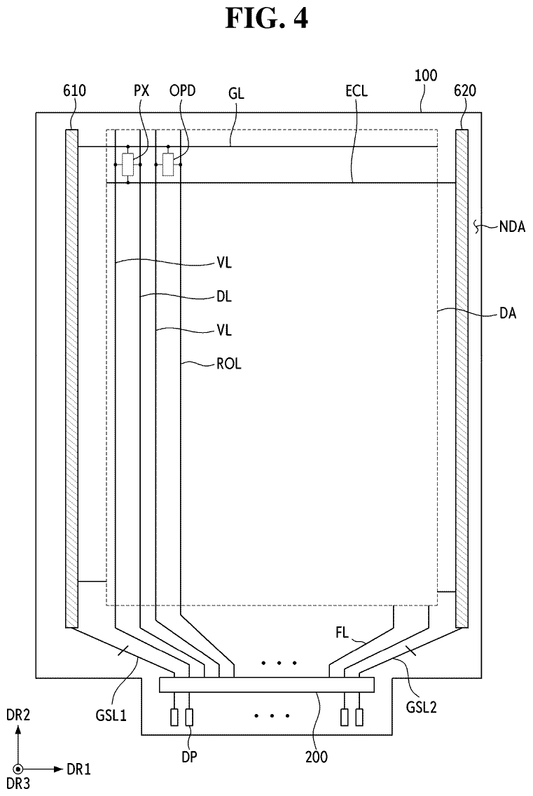

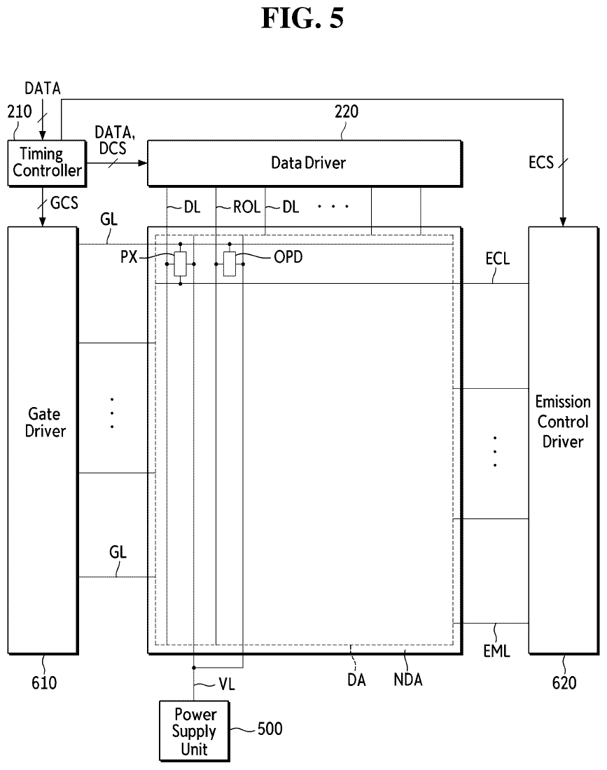

FIG. 4 is a plan view illustrating a light emitting pixel, a sensing pixel, various drivers, and various wires of a display device according to some example embodiments. FIG. 5 is a block diagram illustrating a light emitting pixel, a sensing pixel, various drivers, and various wires of a display device according to some example embodiments.

Referring to FIGS. 4 and 5, the display panel 100 may include the display area DA and the non-display area NDA. The display area DA may include a light emitting pixel PX, a sensing pixel OPD, a power line VL, a data line DL, a read-out line ROL, a gate line GL, and an emission control line ECL.

Each of the plurality of light emitting pixels PX may be connected to the gate line GL, the emission control line ECL, the data line DL, and the power line VL. For example, in some example embodiments there may be four terminals for each of the plurality of light emitting pixels PX. Each of the light emitting pixels PX may include a plurality of transistors, at least one light emitting element, and at least one capacitor.

Each of the plurality of sensing pixels OPD may be connected to the gate line GL, the power line VL, and the read-out line ROL. For example, in some example embodiments there may be three terminals for each of the plurality of sensing pixels OPD. Each of the plurality of sensing pixels OPD may include a plurality of transistors and at least one light receiving element.

The gate lines GL may extend in the first direction DR1 and may be spaced apart from each other in the second direction DR2 intersecting the first direction DR1. The gate lines GL may sequentially supply a gate signal to the light emitting pixels PX and to the sensing pixels OPD. The gate signal applied to the light emitting pixels PX may be the same as the gate signal applied to the sensing pixels OPD, however, example embodiments are not limited thereto.

The emission control lines ECL may extend in the first direction DR1 and may be spaced apart from each other in the second direction DR2. The emission control lines ECL may sequentially supply an emission signal to the plurality of light emitting pixels PX.

The data lines DL may extend in the second direction DR2 and may be spaced apart from each other in the first direction DR1. The data lines DL may supply a data voltage to the plurality of light emitting pixels PX. The data voltage may determine the luminance of each of the light emitting pixels PX.

The power lines VL may extend in the second direction DR2 and may be spaced apart from each other in the first direction DR1. The power line VL may supply a power voltage to the light emitting pixels PX and the sensing pixels OPD, and in some example embodiments may apply the same voltage to the plurality of light emitting pixels PX as the plurality of sensing pixels OPD. Here, the power voltage may be one or more of a driving voltage, a common voltage, an initialization voltage, a reference voltage, a bias voltage, or a reset voltage. The driving voltage may be a high potential voltage for driving the light emitting pixel PX, and the common voltage may be a low potential voltage for driving the light emitting pixel PX and the sensing pixel OPD.

The non-display area NDA may surround, or at least partially surround, the display area DA. The non-display area NDA may include a gate driver 610, an emission control driver 620, fan-out lines FL, a first gate control line GSL1, and a second gate control line GSL2.

The fan-out lines FL may extend from the display driver 200 to the display area DA. The fan-out lines FL may supply the data voltage received from the display driver 200 to the data line DL, supply the power voltage received from the display driver 200 to the power line VL, and supply the sensing signal received from the read-out line ROL to the display driver 200. Accordingly, the display driver 200 may drive the light emitting pixel SP and the sensing pixel OPD.

The first gate control line GSL1 may extend from the display driver 200 to the gate driver 610. The first gate control line GSL1 may supply a gate control signal GCS received from the display driver 200 to the gate driver 610.

The second gate control line GSL2 may extend from the display driver 200 to the emission control driver 620. The second gate control line GSL2 may supply an emission control signal ECS received from the display driver 200 to the emission control driver 620.

The sub-region SBA may extend from one side of the non-display area NDA. The sub-region SBA may include the display driver 200 and a pad portion DP. The pad portion DP may be disposed closer to one edge of the sub-region SBA than the display driver 200. The pad portion DP may be electrically connected to the circuit board 300, for example, through an anisotropic conductive film (ACF).

The display driver 200 may include a timing controller 210 and a data driver 220.

The timing controller 210 may receive digital video data DATA and timing signals from the circuit board 300. The timing controller 210 may generate a data control signal DCS based on the timing signals, and may supply the digital video data DATA and the data control signal DCS to the data driver 220 to control the operation timing of the data driver 220. The timing controller 210 may generate a gate control signal GCS and supply it to the gate driver 610, thus controlling the operation timing of the gate driver 610. The timing controller 210 may generate the emission control signal ECS and may supply the emission control signal ECS to the emission control driver 620, thus controlling the operation timing of the emission control driver 620.

The data driver 220 may convert the digital video data DATA into analog data voltages and supply them to the data lines DL through the fan-out lines FL. The gate signals of the gate driver 610 may select the light emitting pixels PX to which the data voltage is supplied, and the selected light emitting pixels PX may receive the data voltage through the data lines DL. The data driver 220 may supply a sensing signal received through the read-out line ROL to the main processor.

The power supply unit 500 may be disposed on the circuit board 300 to supply a power voltage to the display driver 200 and the display panel 100. The power supply unit 500 may generate a power voltage and supply the power voltage to the power line VL, and may generate a common voltage and supply it to the common electrode that is common to the light emitting pixels PX and the sensing pixels OPD. The power supply unit 500 may generate an initialization voltage to supply it to an initialization voltage line, generate a reference voltage to supply it to a reference voltage line, generate a bias voltage to supply the bias voltage to a bias voltage line, and generate a reset voltage to supply the reset voltage to a reset voltage line.

The gate driver 610 may be disposed at one external side of the display area DA or at one side of the non-display area NDA. The emission control driver 620 may be disposed at the other external side of the display area DA or at the other side of the non-display area NDA. However, example embodiments are not limited thereto. As another example, the gate driver 610 and the emission control driver 620 may be disposed at any one of one side and the other side of the non-display area NDA.

The gate driver 610 may include a plurality of transistors for generating gate signals based on the gate control signal GCS. The emission control driver 620 may include a plurality of transistors for generating emission signals based on the emission control signal ECS. For example, the transistors of the gate driver 610 and the transistors of the emission control driver 620 may be formed on the same layer as the transistors of each of the light emitting pixels PX. The gate driver 610 may supply the gate signals to the gate lines GL, and the emission control driver 620 may supply the emission signals to the emission control lines ECL.

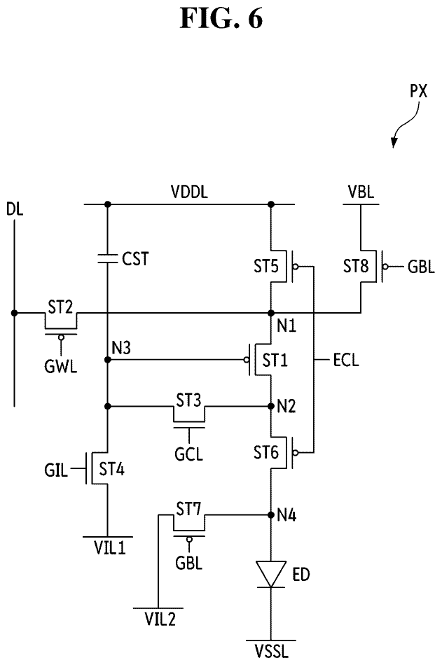

FIG. 6 is a circuit diagram illustrating a light emitting pixel of a display device according to some example embodiments.

Referring to FIG. 6, the light emitting pixel PX may be connected to a first gate line GWL, a second gate line GCL, a third gate line GIL, a fourth gate line GBL, the emission control line ECL, the data line DL, a driving voltage line VDDL, a first initialization voltage line VIL1, a second initialization voltage line VIL2, a bias voltage line VBL, and a low potential line VSSL.

The light emitting pixel PX may include a light emitting element ED and a light emitting pixel circuit for driving the light emitting element ED. The light emitting pixel circuit may include first to eighth transistors ST1, ST2, ST3, ST4, ST5, ST6, ST7, and ST8 and a capacitor CST. First transistor ST1, second transistor ST2, fifth transistor ST5, sixth transistor ST6, seventh transistor ST7, and eighth transistor ST8 are illustrated as being PMOS transistors while third and fourth transistors ST3 and ST4 are illustrated as being NMOS transistors; however, example embodiments are not limited thereto.

The first transistor ST1 may control a driving current supplied to the light emitting element ED. The first transistor ST1 may include a gate electrode, a first electrode, and a second electrode. The gate electrode of the first transistor ST1 may be connected to a third node N3, the first electrode thereof may be connected to a first node N1, and the second electrode thereof may be connected to a second node N2. For example, the first electrode of the first transistor ST1 may be a source electrode and the second electrode thereof may be a drain electrode, but example embodiments are not limited thereto.

The first transistor ST1 may control a source-drain current Isd (hereinafter, referred to as “driving current”) according to the data voltage applied to the gate electrode. The driving current flowing through the channel of the first transistor ST1 may be proportional to the square of a difference between a threshold voltage Vth and a voltage Vsg between the source electrode and the gate electrode of the first transistor ST1 (Isd=k×(Vsg−Vth)²). Here, k is a proportionality coefficient determined by the structure, geometry, electrical, and physical characteristics of the first transistor ST1, Vsg is a source-gate voltage of the first transistor ST1, and Vth is a threshold voltage of the first transistor ST1.

The light emitting element ED may emit light by receiving a driving current. The light emission amount or the luminance of the light emitting element ED may be proportional to the magnitude of the driving current. The light emitting element ED may include a first electrode, a second electrode, and a light emitting layer disposed between the first electrode and the second electrode. The first electrode of the light emitting element ED may be connected to a fourth node N4. The first electrode of the light emitting element ED may be connected to the second electrode of the sixth transistor ST6 and the first electrode of the seventh transistor ST7 through the fourth node N4. The second electrode of the light emitting element ED may be electrically connected to the low potential line VSSL. The second electrode of the light emitting element ED may receive the low potential voltage from the low potential line VSSL. For example, the first electrode of the light emitting element ED may be an anode electrode or a pixel electrode, and the second electrode thereof may be a cathode electrode or a common electrode, but example embodiments are not limited thereto.

The second transistor ST2 may be turned on by the first gate signal of the first gate line GWL to electrically connect the data line DL to the first node N1 which is the first electrode of the first transistor ST1. The second transistor ST2 may be turned on based on the first gate signal to supply the data voltage to the first node N1. The gate electrode of the second transistor ST2 may be connected to the first gate line GWL, the first electrode thereof may be connected to the data line DL, and the second electrode thereof may be connected to the first node N1. The second electrode of the second transistor ST2 may be connected to the first electrode of the first transistor ST1, the second electrode of the fifth transistor ST5, and the second electrode of the eighth transistor ST8 through the first node N1. For example, the first electrode of the second transistor ST2 may be a source electrode and the second electrode thereof may be a drain electrode, but example embodiments are not limited thereto.

The third transistor ST3 may be turned on by the second gate signal of the second gate line GCL to electrically connect the second node N2, which is the second electrode of the first transistor ST1, to the third node N3, which is the gate electrode the first transistor ST1. The gate electrode of the third transistor ST3 may be connected to the second gate line GCL, the first electrode thereof may be connected to the second node N2, and the second electrode thereof may be connected to the third node N3. The first electrode of the third transistor ST3 may be connected to the second electrode of the first transistor ST1 and the first electrode of the sixth transistor ST6 through the second node N2. The second electrode of the third transistor ST3 may be connected to the gate electrode of the first transistor ST1, the first electrode of the fourth transistor ST4, and a first capacitor electrode of the capacitor CST through the third node N3. For example, the first electrode of the third transistor ST3 may be a drain electrode and the second electrode thereof may be a source electrode, but example embodiments are not limited thereto.

The fourth transistor ST4 may be turned on by a third gate signal of the third gate line GIL to electrically connect the third node N3, which is the gate electrode of the first transistor ST1, to the first initialization voltage line VIL1. The fourth transistor ST4 may be turned on based on the third gate signal, thereby discharging the gate electrode of the first transistor ST1 to a first initialization voltage. The gate electrode of the fourth transistor ST4 may be connected to the third gate line GIL, the first electrode thereof may be connected to the third node N3, and the second electrode thereof may be connected to the first initialization voltage line VIL1. The first electrode of the fourth transistor ST4 may be connected to the gate electrode of the first transistor ST1, the second electrode of the third transistor ST3, and the first capacitor electrode of the capacitor CST through the third node N3. For example, the first electrode of the fourth transistor ST4 may be a drain electrode and the second electrode thereof may be a source electrode, but example embodiments are not limited thereto.

The fifth transistor ST5 may be turned on by an emission signal of the emission control line ECL to electrically connect the driving voltage line VDDL with the first node N1 that is the first electrode of the first transistor ST1. The gate electrode of the fifth transistor ST5 may be connected to the emission control line ECL, the first electrode thereof may be connected to the driving voltage line VDDL, and the second electrode thereof may be connected to the first node N1. The second electrode of the fifth transistor ST5 may be electrically connected to the first electrode of the first transistor ST1, the second electrode of the second transistor ST2, and the second electrode of the eighth transistor ST8 through the first node N1. For example, the first electrode of the fifth transistor ST5 may be a source electrode and the second electrode thereof may be a drain electrode, but example embodiments are not limited thereto.

The sixth transistor ST6 may be turned on by the emission signal of the emission control line ECL to electrically connect the second node N2 that is the second electrode of the first transistor ST1 with the fourth node N4 that is the first electrode of the light emitting element ED. The gate electrode of the sixth transistor ST6 may be connected to the emission control line ECL, the first electrode thereof may be connected to the second node N2, and the second electrode thereof may be connected to the fourth node N4. The first electrode of the sixth transistor ST6 may be connected to the second electrode of the first transistor ST1 and the first electrode of the third transistor ST3 through the second node N2. The second electrode of the sixth transistor ST6 may be connected to the first electrode of the light emitting element ED and the first electrode of the seventh transistor ST7 through the fourth node N4. For example, the first electrode of the sixth transistor ST6 may be a source electrode and the second electrode thereof may be a drain electrode, but example embodiments are not limited thereto.

When each of the first transistor ST1, the fifth transistor ST5, and the sixth transistor ST6 are turned on, the driving current may be supplied to the light emitting element ED.

The seventh transistor ST7 may be turned on by the fourth gate signal of the fourth gate line GBL to electrically connect the second initialization voltage line VIL2 to the fourth node N4, which is the first electrode of the light emitting element ED. By turning on the seventh transistor ST7 based on the fourth gate signal, the first electrode of the light emitting element ED may be discharged to a second initialization voltage. The gate electrode of the seventh transistor ST7 may be connected to the fourth gate line GBL, the first electrode thereof may be connected to the fourth node N4, and the second electrode thereof may be connected to the second initialization voltage line VIL2. The first electrode of the seventh transistor ST7 may be connected to the first electrode of the light emitting element ED and the second electrode of the sixth transistor ST6 through the fourth node N4. For example, the first electrode of the seventh transistor ST7 may be a source electrode and the second electrode thereof may be a drain electrode, but example embodiments are not limited thereto.

The eighth transistor ST8 may be turned on by the fourth gate signal of the fourth gate line GBL to electrically connect the bias voltage line VBL with the first node N1 that is the first electrode of the first transistor ST1. The gate electrode of the eighth transistor ST8 may be connected to the fourth gate line GBL, the first electrode thereof may be connected to the bias voltage line VBL, and the second electrode thereof may be connected to the first node N1. The second electrode of the eighth transistor ST8 may be electrically connected to the first electrode of the first transistor ST1, the second electrode of the second transistor ST2, and the second electrode of the fifth transistor ST5 through the first node N1. For example, the first electrode of the eighth transistor ST8 may be a source electrode and the second electrode thereof may be a drain electrode, but example embodiments are not limited thereto. Optionally, the eighth transistor ST8 may be omitted.

Each of the first transistor ST1, the second transistor ST2, the fifth transistor ST5, the sixth transistor ST6, the seventh transistor ST7, and the eighth transistor ST8 may include a silicon-based semiconductor region; example embodiments are not limited thereto. For example, each of the first transistor ST1, the second transistor ST2, the fifth transistor ST5, the sixth transistor ST6, the seventh transistor ST7, and the eighth transistor ST8 may include a semiconductor region made of low temperature polycrystalline silicon (LTPS). The semiconductor region made of low temperature polycrystalline silicon may have high electron mobility and good or excellent turn-on characteristics. Accordingly, since the display device 10 includes the first transistor ST1, the second transistor ST2, the fifth transistor ST5, the sixth transistor ST6, the seventh transistor ST7, and the eighth transistor ST8 having excellent turn-on characteristics, the plurality of light emitting pixels PX can be driven stably and efficiently.

Each of the first, second, fifth, sixth, seventh, and eighth transistors ST1, ST2, ST5, ST6, ST7, and ST8 may correspond to a p-type transistor; example embodiments are not limited thereto. For example, each of the first transistor ST1, the second transistor ST2, the fifth transistor ST5, the sixth transistor ST6, the seventh transistor ST7, and the eighth transistor ST8 may output a current flowing into the first electrode to the second electrode based on a gate low voltage applied to the gate electrode.

Each of the third transistor ST3 and the fourth transistor ST4 may include an oxide-based semiconductor region; example embodiments are not limited thereto. For example, each of the third transistor ST3 and the fourth transistor ST4 may have a coplanar structure in which the gate electrode is disposed on the oxide-based semiconductor region. The transistor having the coplanar structure may have excellent leakage current characteristics and perform low frequency driving, thereby reducing power consumption. Accordingly, the display device 10 may include the third transistor ST3 and the fourth transistor ST4 having improved or excellent leakage current characteristics, thereby preventing a leakage current from flowing in the light emitting pixel, and stably maintaining the voltage in the light emitting pixel.

Each of the third transistor ST3 and the fourth transistor ST4 may correspond to an n-type transistor. For example, each of the third transistor ST3 and the fourth transistor ST4 may output a current flowing into the first electrode to the second electrode based on a gate high voltage applied to the gate electrode.

At least one electrical and/or physical property of transistors ST1, ST2, ST5, ST6, ST7, and ST8 may be the same; alternatively, at least one electrical and/or at least one physical property of one or more of transistors ST1, ST2, ST5, ST6, ST7, and ST8 may be different than others of transistors ST1, ST2, ST5, ST6, ST7, and ST8. Alternatively or additionally, at least one electrical and/or physical property of transistor ST3 and ST4 may be different.

The capacitor CST may be connected between the third node N3, which is the gate electrode of the first transistor ST1, and the driving voltage line VDDL. For example, the first capacitor electrode of the capacitor CST may be connected to the third node N3, and the second capacitor electrode of the capacitor CST may be connected to the driving voltage line VDDL, thereby maintaining a potential difference between the driving voltage line VDDL and the gate electrode of the first transistor ST1.

FIG. 7 is a cross-sectional view illustrating a light emitting pixel of a display device according to some example embodiments.

Referring to FIG. 7 in addition to FIG. 6, the display panel 100 may include the substrate SUB, the transistor layer TFTL, the element layer EML, and the encapsulation layer TFEL. The light emitting pixel PX may include the light emitting pixel circuit and the light emitting element ED. The light emitting pixel circuit may be disposed in the transistor layer TFTL, and the light emitting element ED may be disposed in the element layer EML.

The substrate SUB may be or may include a base substrate or a base member. The substrate SUB may be or may include a flexible substrate which can be bent, folded, and/or rolled. For example, the substrate SUB may include a polymer resin such as polyimide, but is not limited thereto. Alternatively or additionally, the substrate SUB may include a glass material and/or a metal material.

The transistor layer TFTL may include a buffer layer BF, a first active layer ACTL1, a first gate insulating layer GI1, a first gate layer GTL1, a second gate insulating layer GI2, a second gate layer GTL2, a first interlayer insulating layer ILD1, a second active layer ACTL2, a third gate insulating layer GI3, a third gate layer GTL3, a second interlayer insulating layer ILD2, a first source metal layer SDL1, a first via layer VIA1, a second source metal layer SDL2, and a second via layer VIA2.

The buffer layer BF may be disposed on the substrate SUB. For example, the buffer layer BF may include an inorganic film capable of preventing or reducing the likelihood of and/or impact from permeation of air and/or moisture. For example, the buffer layer BF may include a plurality of inorganic films laminated alternately, having the same or different thicknesses and/or the same or different material composition.

The first active layer ACTL1 may be disposed on the buffer layer BF. The first active layer ACTL1 may include a silicon-based material. For example, the first active layer ACTL1 may be formed of low temperature polycrystalline silicon (LTPS). The first active layer ACTL1 may include the semiconductor region ACT1, the first electrode SE1, and the second electrode DE1 of the first transistor ST1, and the semiconductor region ACT2, the first electrode SE2, and the second electrode DE2 of the second transistor ST2.

The first gate insulating layer GI1 may be disposed on the first active layer ACTL1. The first gate insulating layer GI1 may insulate the first active layer ACTL1 from the first gate layer GTL1.

The first gate layer GTL1 may be disposed on the first gate insulating layer GI1. The first gate layer GTL1 may include the gate electrode GE1 of the first transistor ST1, the gate electrode GE2 of the second transistor ST2, and the first capacitor electrode CPE1. The gate electrode GE1 of the first transistor ST1 may be a part of the first capacitor electrode CPE1, and the gate electrode GE2 of the second transistor ST2 may be a part of the first gate line GWL.

The second gate insulating layer GI2 may be disposed on the first gate layer GTL1. The second gate insulating layer GI2 may insulate the first gate layer GTL1 from the second gate layer GTL2.

The second gate layer GTL2 may be disposed on the second gate insulating layer GI2. The second gate layer GTL2 may include a second capacitor electrode CPE2. The second capacitor electrode CPE2 may overlap the first capacitor electrode CPE1.

The first interlayer insulating layer ILD1 may be disposed on the second gate layer GTL2. The first interlayer insulating layer ILD1 may insulate the second gate layer GTL2 from the second active layer ACTL2.

The second active layer ACTL2 may be disposed on the first interlayer insulating layer ILD1. The second active layer ACTL2 may include an oxide-based material. The second active layer ACTL2 may include the semiconductor region ACT3, the first electrode DE3, and the second electrode SE3 of the third transistor ST3.

The third gate insulating layer GI3 may be disposed on the second active layer ACTL2. The third gate insulating layer GI3 may insulate the second active layer ACTL2 from the third gate layer GTL3.

The third gate layer GTL3 may be disposed on the third gate insulating layer GI3. The third gate layer GTL3 may include a gate electrode GE3 of the third transistor ST3. The gate electrode GE3 of the third transistor ST3 may be a part of the second gate line GCL.

The second interlayer insulating layer ILD2 may be disposed on the third gate layer GTL3. The second interlayer insulating layer ILD2 may insulate the third gate layer GTL3 from the first source metal layer SDL1.

The first source metal layer SDL1 may be disposed on the second interlayer insulating layer ILD2. The first source metal layer SDL1 may include first to third connection electrodes CE1, CE2, and CE3. The first connection electrode CE1 may electrically connect the data line DL to the first electrode SE2 of the second transistor ST2. The second connection electrode CE2 may electrically connect the first capacitor electrode CPE1 to the second electrode SE3 of the third transistor ST3. The third connection electrode CE3 may electrically connect the first electrode DE3 of the third transistor ST3 to the second electrode DE1 of the first transistor ST1.

Thicknesses of and/or material compositions of each of the first interlayer insulating layer ILD1 and the second interlayer insulating layer ILD2 may be the same, or different. Alternatively or additionally, thicknesses of and/or material compositions of each of the gate insulating layer GI1 to GI3 may be the same, or different. Example embodiments are not limited thereto.

The first via layer VIA1 may be disposed on the first source metal layer SDL1. The first via layer VIA1 may insulate the first source metal layer SDL1 from the second source metal layer SDL2. The top surface of the first via layer VIA1 may be flat or planar. The first via layer VIA1 may contain an organic insulating material such as polyimide (PI).

The second source metal layer SDL2 may be disposed on the first via layer VIA1. The second source metal layer SDL2 may include the data line DL.

The second via layer VIA2 may be disposed on the second source metal layer SDL2. The second via layer VIA2 may insulate the second source metal layer SDL2 from a pixel electrode AE. The top surface of the second via layer VIA2 may be flat. The second via layer VIA2 may contain an organic insulating material such as polyimide (PI), and may or may not be the same thickness as, and/or may or may not include the same material as that of the first via layer VIA1.

The element layer EML may include a pixel defining film PDL and the light emitting element ED.

The pixel defining film PDL may be disposed on the second via layer VIA2. The pixel defining film PDL may define a plurality of emission areas LA. The pixel defining film PDL may include an organic insulating material such as polyimide (PI), but is not limited thereto.

The light emitting element ED may include the pixel electrode AE, the hole transporting layer HTL, the light emitting layer EL, the electron transporting layer ETL, and the common electrode CAT. The pixel electrode AE may be disposed on the second via layer VIA2. The pixel electrode AE may overlap one of the plurality of emission areas LA defined by the pixel defining film PDL. The pixel electrode AE may receive a driving current from the pixel circuit of the light emitting pixel PX.

The hole transporting layer HTL may be disposed on the pixel electrode AE in the emission area LA and may be disposed on the pixel defining film PDL in an area other than the emission area LA. The hole transporting layer HTL may be implemented as a common layer for all the light emitting pixels PX and the sensing pixels OPD, rather than being divided for each light emitting pixel PX.

The light emitting layer EL may be disposed on the hole transporting layer HTL in the emission area LA. For example, the light emitting layer EL may be an organic light emitting layer made of an organic material, but is not limited thereto.

The electron transporting layer ETL may be disposed on the light emitting layer EL in the emission area LA and may be disposed on the hole transporting layer HTL in an area other than the emission area LA. The electron transporting layer ETL may be implemented as a common layer for all the light emitting pixels PX and the sensing pixels OPD, rather than being divided for each light emitting pixel PX.

The common electrode CAT may be disposed on the electron transporting layer ETL. For example, the common electrode CAT may be implemented in the form of an electrode that is common to all the light emitting pixels PX and the sensing pixels OPD, rather than being divided for each of the plurality of light emitting pixels PX. The common electrode CAT may be a transparent electrode and may allow light to pass therethrough. The common electrode CAT may be electrically connected to the low potential line VSSL and may receive a low potential voltage, a common voltage, or a cathode voltage.

In a case where the light emitting layer EL corresponds to an organic light emitting layer, when a voltage, such as but not limited to a predetermined voltage is applied to the pixel electrode AE in the pixel circuit of the light emitting pixel PX, and the common electrode CAT receives a common voltage or a cathode voltage, holes may move to the light emitting layer EL through the hole transporting layer HTL, electrons may move to the light emitting layer EL through the electron transporting layer ETL, and the holes and the electrons may combine with each other in the light emitting layer EL to emit light.

The encapsulation layer TFEL may be disposed on the common electrode CAT to cover the plurality of light emitting elements ED. The encapsulation layer TFEL may include at least one inorganic film to prevent or reduce the likelihood of and/or impact from oxygen or moisture from permeating into the plurality of light emitting elements ED. The encapsulation layer TFEL may include at least one organic film to protect the plurality of light emitting elements ED from foreign matters such as dust.

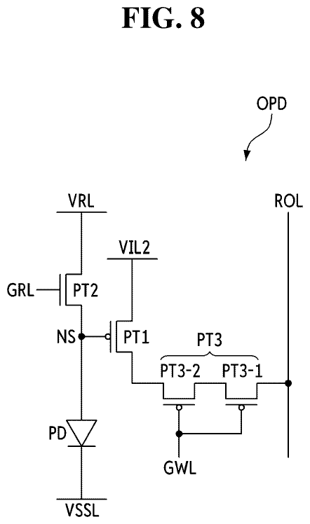

FIG. 8 is a circuit diagram of a sensing pixel of a display device according to some example embodiments.

Referring to FIG. 8, the sensing pixel OPD may be connected to the first gate line GWL, the reset signal line GRL, the reset voltage line VRL, the second initialization voltage line VIL2, the low potential line VSSL, and the read-out line ROL.

The sensing pixel OPD may include a light receiving element PD and a sensing pixel circuit for driving the light receiving element PD. The sensing pixel circuit may include first to third sensor transistors PT1, PT2, and PT3.

The first sensor transistor PT1 may include a gate electrode, a first electrode, and a second electrode. The gate electrode of the first sensor transistor PT1 may be connected to the sensor node NS, the first electrode thereof may be connected to the third sensor transistor PT3, and the second electrode thereof may be connected to the second initialization voltage line VIL2. The first sensor transistor PT1 may control the source-drain current Isd (hereinafter referred to as “sensing current”) based on the voltage of the sensor node NS, which is the first electrode of the light receiving element PD. The sensing current flowing through the channel of the first sensor transistor PT1 may be proportional to the square of a difference between the threshold voltage Vth and the voltage Vsg between the source electrode and the gate electrode of the first sensor transistor PT1 (Isd=k′×(Vsg−Vth)²). Here, k′ is a proportional coefficient determined by the structure and physical characteristics of the first sensor transistor PT1, Vsg is a source-gate voltage of the first sensor transistor PT1, and Vth is a threshold voltage of the first sensor transistor PT1. The first electrode of the first sensor transistor PT1 may be a source electrode and the second electrode thereof may be a drain electrode, but example embodiments are not limited thereto.

The second sensor transistor PT2 may be turned on by the reset signal of the reset signal line GRL, thereby discharging the voltage of the sensor node NS to the reset voltage. The gate electrode of the second sensor transistor PT2 may be connected to the reset signal line GRL, the first electrode thereof may be connected to the sensor node NS, and the second electrode thereof may be connected to the reset voltage line VRL. The first electrode of the second sensor transistor PT2 may be connected to the first electrode of the light receiving element PD and the gate electrode of the first sensor transistor PT1 through the sensor node NS. The first electrode of the second sensor transistor PT2 may be a drain electrode and the second electrode thereof may be a source electrode, but is not limited thereto.

The third sensor transistor PT3 may be turned on by the first gate signal of the first gate line GWL to electrically connect the first electrode of the first sensor transistor PT1 to the read-out line ROL. The third sensor transistor PT3 may include a third-first sensor transistor PT3-1 and a third-second sensor transistor PT3-2 connected in series. The third-first sensor transistor PT3-1 and the third-second sensor transistor PT3-2 may be connected in series between the first electrode of the first sensor transistor PT1 and the read-out line ROL. The gate electrode of the third-first sensor transistor PT3-1 and the gate electrode of the third-second sensor transistor PT3-2 may be integrally formed and electrically connected to the first gate line GWL. The first electrode of the third-first sensor transistor PT3-1 may be connected to the read-out line ROL, and the second electrode of the third-second sensor transistor PT3-2 may be connected to the first electrode of the first sensor transistor PT1. The second electrode of the third-first sensor transistor PT3-1 and the first electrode of the third-second sensor transistor PT3-2 may be integrally formed. The first electrode of each of the third-first sensor transistor PT3-1 and the third-second sensor transistor PT3-2 may be a source electrode and the second electrode thereof may be a drain electrode, but example embodiments are not limited thereto.

The light receiving element PD may receive light and convert light energy into an electrical signal. The first electrode of the light receiving element PD may be connected to the sensor node NS, which is the gate electrode of the first sensor transistor PT1, and the second electrode thereof may be connected to the low potential line VSSL. The second electrode of the light receiving element PD may receive the low potential voltage from the low potential line VSSL. For example, the first electrode of the light receiving element PD may be or may include a sensor electrode, and the second electrode thereof may be or may include a common electrode, but example embodiments are not limited thereto.

When an object is positioned above the display panel 100, light emitted from the light emitting element may be reflected by the object, and the light receiving element PD may receive the reflected light. The light receiving element PD may convert the energy of light into an electrical signal (current and/or voltage) formed between the first and second electrodes, and the converted electrical signal may flow from the low potential line VSSL to the sensor node NS as a reverse bias current. For example, when the light receiving element PD receives light and an electric field is formed between the first and second electrodes of the light receiving element PD, a current may flow through the light receiving element PD in proportion to the amount of light and the voltage at the sensor node NS may increase. Accordingly, when the light receiving element PD receives light, the voltage of the sensor node NS may increase and the magnitude of a sensing current (or source-drain current) of the first sensor transistor PT1 may decrease. The sensing current of the first sensor transistor PT1 may be applied to the display driver 200 as a sensing signal through the third sensor transistor PT3 and the read-out line ROL.

FIG. 9 is a cross-sectional view illustrating a sensing pixel of a display device according to some example embodiments.

Referring to FIG. 9 in addition to FIG. 8, the display panel 100 may include the substrate SUB, the transistor layer TFTL, the element layer EML, and the encapsulation layer TFEL. The sensing pixel OPD may include the sensing pixel circuit and the light receiving element PD. The sensing pixel circuit may be disposed in the transistor layer TFTL, and the light receiving element PD may be disposed in the element layer EML.

Descriptions of the substrate SUB and the encapsulation layer TFEL have been previously provided with reference to FIG. 7 and are therefore omitted here.

The transistor layer TFTL may include the buffer layer BF, the first active layer ACTL1, the first gate insulating layer GI1, the first gate layer GTL1, the second gate insulating layer GI2, the first interlayer insulating layer ILD1, the second active layer ACTL2, the third gate insulating layer GI3, the third gate layer GTL3, the second interlayer insulating layer ILD2, the first source metal layer SDL1, the first via layer VIA1, the second source metal layer SDL2, and the second via layer VIA2.

Descriptions of the buffer layer BF, the first gate insulating layer GI1, the second gate insulating layer GI2, the first interlayer insulating layer ILD1, the third gate insulating layer GI3, the second interlayer insulating layer ILD2, the first via layer VIA1, and the second via layer VIA2 of the transistor layer TFTL have been previously provided with reference to FIG. 7 and are therefore omitted here.

The first active layer ACTL1 may be disposed on the buffer layer BF. The first active layer ACTL1 may include a silicon-based material. For example, the first active layer ACTL1 may be formed of low temperature polycrystalline silicon (LTPS). The first active layer ACTL1 may include a semiconductor region PACT1, a first electrode PSE1, and a second electrode PDE1 of the first sensor transistor PT1.

The first gate layer GTL1 may be disposed on the first gate insulating layer GI1. The first gate layer GTL1 may include a gate electrode PGE1 of the first sensor transistor PT1.

The second active layer ACTL2 may be disposed on the first interlayer insulating layer ILD1. The second active layer ACTL2 may include an oxide-based material. The second active layer ACTL2 may include a semiconductor region PACT2, a first electrode PDE2, and a second electrode PSE2 of the second sensor transistor PT2.

The third gate layer GTL3 may be disposed on the third gate insulating layer GI3. The third gate layer GTL3 may include a gate electrode PGE2 of the second sensor transistor PT2. The gate electrode PGE2 of the second sensor transistor PT2 may be a portion of the reset signal line GRL.

The first source metal layer SDL1 may be disposed on the second interlayer insulating layer ILD2. The first source metal layer SDL1 may include a sensor connection electrode PCE and a first sensor node electrode NSE1. The sensor connection electrode PCE may electrically connect the reset voltage line VRL to the second electrode PSE2 of the second sensor transistor PT2. The first sensor node electrode NSE1 may electrically connect the first electrode PDE2 of the second sensor transistor PT2 to the gate electrode PGE1 of the first sensor transistor PT1.

The second source metal layer SDL2 may be disposed on the first via layer VIA1. The second source metal layer SDL2 may include the reset voltage line VRL and a second sensor node electrode NSE2. The second sensor node electrode NSE2 may electrically connect a sensor electrode PE to the first sensor node electrode NSE1.

The light receiving element PD may include the sensor electrode PE, the hole transporting layer HTL, the light receiving layer RCL, the electron transporting layer ETL, and the common electrode CAT. The sensor electrode PE may be disposed on the second via layer VIA2 and may be disposed in the same layer as the pixel electrode AE of the light emitting element ED. The sensor electrode PE may overlap one of a plurality of sensing areas PDA defined by the pixel defining film PDL.

The hole transporting layer HTL may be disposed on the sensor electrode PE in the sensing area PDA and may be disposed on the pixel defining film PDL in an area other than the sensing area PDA. The hole transporting layer HTL may be implemented as a common layer for all the light emitting pixels PX and the sensing pixels OPD, rather than being divided for each sensing pixel OPD.

The light receiving layer RCL may be disposed on the hole transporting layer HTL. The light receiving layer RCL may receive light emitted from the emission area LA and reflected by the object. The light emitted from the light emitting element ED of the emission area LA may be reflected by the object, and the reflected light may reach the light receiving layer RCL. The light receiving element PD may convert the energy of light into an electrical signal (current or voltage) formed between the sensor electrode PE and the common electrode CAT, and the converted electrical signal may flow to the sensor node NS of FIG. 8 as a reverse bias current. For example, when the light receiving element PD receives light and an electric field is formed between the common electrode CAT and the sensor electrode PE of the light receiving element PD, a current may flow through the light receiving element PD in proportion to the amount of light.

The electron transporting layer ETL may be disposed on the light receiving layer RCL in the sensing area PDA and may be disposed on the hole transporting layer HTL in an area other than the sensing area PDA. The electron transporting layer ETL may be implemented as a common layer for all the light emitting pixels PX and the sensing pixels OPD, rather than being divided for each sensing pixel OPD.

The common electrode CAT may be disposed on the electron transporting layer ETL. For example, the common electrode CAT may be implemented in the form of an electrode that is common to all the light emitting pixels PX and the sensing pixels OPD, rather than being divided for each of the plurality of light emitting pixels PX. The common electrode CAT may be a transparent electrode and may allow light to pass therethrough. The common electrode CAT may be electrically connected to the low potential line VSSL and may receive a low potential voltage, a common voltage, or a cathode voltage.

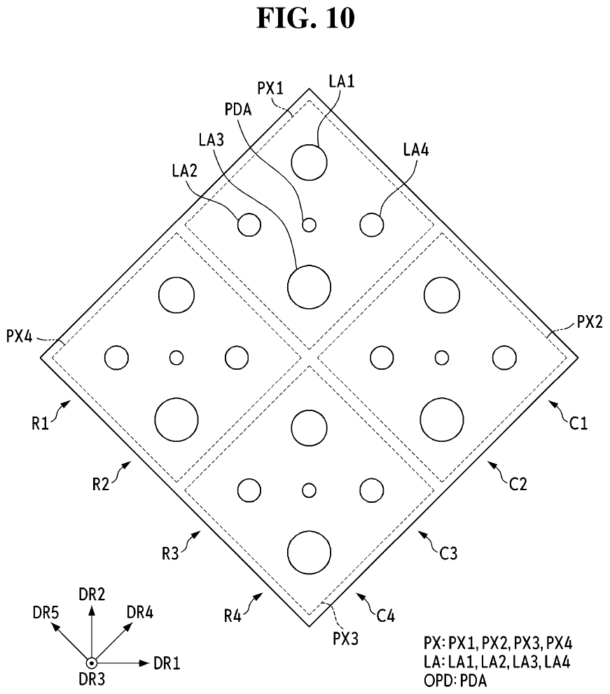

FIG. 10 is a plan view illustrating an emission area and a sensing area in a display device according to some example embodiments.

Referring to FIG. 10 in addition to FIGS. 6 to 9, the display device 10 may include the plurality of light emitting pixels PX. For example, the plurality of light emitting pixels PX may include first to fourth light emitting pixels PX1, PX2, PX3, and PX4.

The first to fourth pixels PX1, PX2, PX3, and PX4 may be arranged in a fourth direction DR4 and a fifth direction DR5, which are diagonal directions between the first direction DR1 and the second direction DR2. For example, the first light emitting pixel PX1 and the second light emitting pixel PX2 may be disposed adjacent in the fifth direction DR5, the second light emitting pixel PX2 and the third light emitting pixel PX3 may be disposed adjacent in the fourth direction DR4, and the third light emitting pixel PX3 and the fourth light emitting pixel PX4 may be disposed adjacent in the fifth direction DR5, and the fourth light emitting pixel PX4 and the first light emitting pixel PX1 may be disposed adjacent in the fourth direction DR4. The first to fourth pixels PX1, PX2, PX3, and PX4 may be repeatedly disposed in the arrangement of FIG. 10 over the entire display area DA.

Each of the plurality of first to fourth light emitting pixels PX1, PX2, PX3, and PX4 may include the plurality of emission areas LA. For example, each of the first to fourth pixels PX1, PX2, PX3, and PX4 may include a first emission area LA1, a second emission area LA2, a third emission area LA3, and a fourth emission area LA4. However, example embodiments are not limited thereto. The number of the emission areas LA disposed in the first to fourth light emitting pixels PX1, PX2, PX3, and PX4 may be variously modified. For example, the arrangement of emission areas LA may correspond to an arrangement of pips on a dice or on dominoes; example embodiments are not limited thereto.

Each of the first to fourth light emitting pixels PX1, PX2, PX3, and PX4 may include at least one light emitting element ED. In some embodiments, one or more light emitting elements ED included in each of the first to fourth light emitting pixels PX1, PX2, PX3, and PX4 may emit the same color or different colors. For example, the light emitting element ED disposed in the first emission area LA1 may emit red first light, the light emitting element ED disposed in the second emission area LA2 may emit green second light, and the light emitting element ED disposed in the third emission area LA3 may emit blue third light. Alternatively or additionally, the light emitting element ED disposed in the fourth emission area LA4 may emit the green second light. However, example embodiments are not limited thereto.

Each emission area LA may emit light of various colors. For example, the first emission area LA1 may emit the red first light, the second emission area LA2 may emit the green second light, the third emission area LA3 may emit the blue third light, and the fourth emission area LA4 may emit the green second light. However, example embodiments are not limited thereto.

In some example embodiments, each emission area LA of the display device 10 may be a region where the light emitting layer EL overlaps the pixel electrode AE. For example, the emission areas LA may be defined by a plurality of openings of the pixel defining film PDL.

The plurality of emission areas LA may be disposed in a PenTile™ type, e.g., a diamond PenTile™ type. For example, the first emission area LA1 and the third emission area LA3 may be spaced apart from each other in the second direction DR2, and they may be alternately disposed in the first direction DR1 and the second direction DR2. The second emission area LA2 and the fourth emission area LA4 may be spaced apart from emission area in the first direction DR1 and the second direction DR2, and may be spaced apart from the adjacent first emission area LA1 and the adjacent third emission area LA3 in the fourth direction DR4 or the fifth direction DR5. The second emission area LA2 and the fourth emission area LA4 may be repeatedly disposed along the first direction DR1 and the second direction DR2, and the second emission area LA2 and the first emission area LA1, or the fourth emission area LA4 and the third emission area LA3 may be alternately disposed along the fourth direction DR4 or the fifth direction DR5.

In a first diagonal column C1, the first emission area LA1 and the fourth emission area LA4 of the first light emitting pixel PX1 and the first emission area LA1 and the fourth emission area LA4 of the second light emitting pixel PX2 may be arranged in the fifth direction DR5. In a second diagonal column C2, e.g., a column parallel to and adjacent to the first diagonal column C1, the second emission area LA2 and the third emission area LA3 of the first light emitting pixel PX1 and the second emission area LA2 and the third emission area LA3 of the second light emitting pixel PX2 may be arranged in the fifth direction DR5. In a third diagonal column C3, e.g., a column parallel to and adjacent to the second diagonal column C2, the first emission area LA1 and the fourth emission area LA4 of the fourth light emitting pixel PX4 and the first emission area LA1 and the fourth emission area LA4 of the third light emitting pixel PX3 may be arranged in the fifth direction DR5. In a fourth diagonal column C4, e.g., a column parallel to and adjacent to the third diagonal column C3, the second emission area LA2 and the third emission area LA3 of the fourth light emitting pixel PX4 and the second emission area LA2 and the third emission area LA3 of the third light emitting pixel PX3 may be arranged in the fifth direction DR5.

In a first diagonal row R1, the first emission area LA1 and the second emission area LA2 of the first light emitting pixel PX1 and the first emission area LA1 and the second emission area LA2 of the fourth light emitting pixel PX4 may be arranged in the fourth direction DR4. In a second diagonal row R2, e.g., a row parallel to and adjacent to the first diagonal row R1, the fourth emission area LA4 and the third emission area LA3 of the first light emitting pixel PX1 and the fourth emission area LA4 and the third emission area LA3 of the fourth light emitting pixel PX4 may be arranged in the fourth direction DR4. In a third diagonal row R3, e.g., a row parallel to and adjacent to the second diagonal row R2, the first emission area LA1 and the second emission area LA2 of the second light emitting pixel PX2 and the first emission area LA1 and the second emission area LA2 of the third light emitting pixel PX3 may be arranged in the fourth direction DR4. In a fourth diagonal row R4, e.g., a row parallel to and adjacent to the third diagonal row R3, the fourth emission area LA4 and the third emission area LA3 of the second light emitting pixel PX2 and the fourth emission area LA4 and the third emission area LA3 of the third light emitting pixel PX3 may be arranged in the fourth direction DR4.

In some example embodiments, the areas and/or sizes of the emission areas LA may be different. In example embodiments illustrated in FIG. 10, the area of the third emission area LA3 may be larger than the areas of the first emission area LA1, the second emission area LA2, and the fourth emission area LA4, and the area of the first emission area LA1 may be larger than the areas of the second emission area LA2 and the fourth emission area LA4. The intensity of light emitted may vary depending on the area of each emission area LA, and by adjusting the area of each emission area LA, the screen color displayed on the display device 10 or the electronic device 1 may be controlled. In example embodiments illustrated in FIG. 10, the third emission area LA3 having the largest area is illustrated, but is not limited thereto. The sizes of the emission areas LA and/or the the areas of the emission areas may be freely adjusted depending on the color of the screen required or used in the display device 10 or the electronic device 1. Alternatively or additionally, the area of and/or shape of each emission area LA may be related to one or more of the light efficiency, the lifespan of the light emitting element ED, and the like, and may have a trade-off relationship with the reflection by external light. The area and/or shape of each emission area LA may be adjusted in consideration of the above factors.

The display device 10 may include the plurality of sensing pixels OPD. The plurality of sensing pixels OPD may respectively overlap the plurality of light emitting pixels PX in the third direction DR3. For example, the plurality of sensing pixels OPD may be disposed approximately at the centers of the plurality of light emitting pixels PX in plan view, but are not limited thereto. The plurality of sensing pixels OPD may be repeatedly arranged in the arrangement of FIG. 10 across the entire display area DA.

The plurality of sensing pixels OPD may respectively include the plurality of sensing areas PDA. The sensing area PDA may receive light emitted from the emission area LA and reflected by the object. One sensing area PDA may include at least one light receiving element PD.

In some example embodiments, each sensing area PDA of the display device 10 may be a region where the light receiving layer RCL overlaps or at least partly overlaps the sensor electrode PE. For example, each of the sensing areas PDA may be defined by a plurality of openings of the pixel defining film PDL.

The sensing area PDA may be surrounded by the emission areas LA. The sensing area PDA may be disposed side by side with the emission areas LA in the first direction DR1 and the second direction DR2, while being spaced apart therefrom. For example, the sensing area PDA may be disposed between the first emission area LA1 and the third emission area LA3 in the second direction DR2, and between the second emission area LA2 and the fourth emission area LA4 in the first direction DR1.

The sensing areas PDA may be spaced apart from each other with at least one emission area LA interposed therebetween. For example, as shown in the drawing, the sensing areas PDA may be spaced apart from each other with the second emission area LA2 and the fourth emission area LA4 interposed therebetween in the first direction DR1, and may be spaced apart from each other with the first emission area LA1 and the third emission area LA3 interposed therebetween in the second direction DR2.

The area of the sensing area PDA may be different from the area of the emission area LA. For example, the area of the sensing area PDA may be smaller than the area of the emission area LA. By increasing the area of the emission area LA, the light emission efficiency may be improved, and by reducing the area of the sensing area PDA and densely arranging the sensing area PDA, the sensing accuracy may be improved. However, example embodiments are not limited thereto.

In the drawings, one sensing area PDA is shown as being disposed between four emission areas LA within a single light emitting pixel PX, but example embodiments are not limited thereto. A greater number of the sensing areas PDA may be disposed between the emission areas LA.

In the drawings, the emission areas LA and the sensing areas PDA are shown as being circular in plan view, but are not limited thereto. The shapes of the emission areas LA and the sensing areas PDA may be variously modified into polygonal, elliptical, or other shapes.

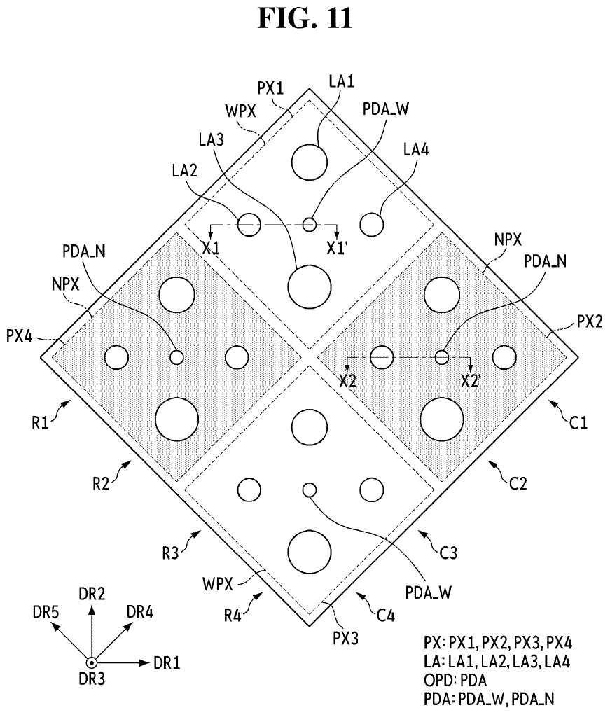

FIG. 11 is a schematic diagram illustrating pixel types according to an emission mode of the display device according to some example embodiments.

Referring to FIG. 11, the display device 10 may include a first type pixel and a second type pixel. For example, the first type pixel may be a normal mode pixel WPX and the second type pixel may be a privacy mode pixel NPX. The first type pixel may include the first light emitting pixel PX1, the third light emitting pixel PX3, and a first sensing area PDA_W. The second type pixel may include the second light emitting pixel PX2, the fourth light emitting pixel PX4, and a second sensing area PDA_N. The first sensing area PDA_W and the second sensing area PDA_N may be included in the sensing area PDA. The first sensing area PDA_W may be the sensing area PDA included in the first type pixel, and the second sensing area PDA_N may be the sensing area PDA included in the second type pixel.

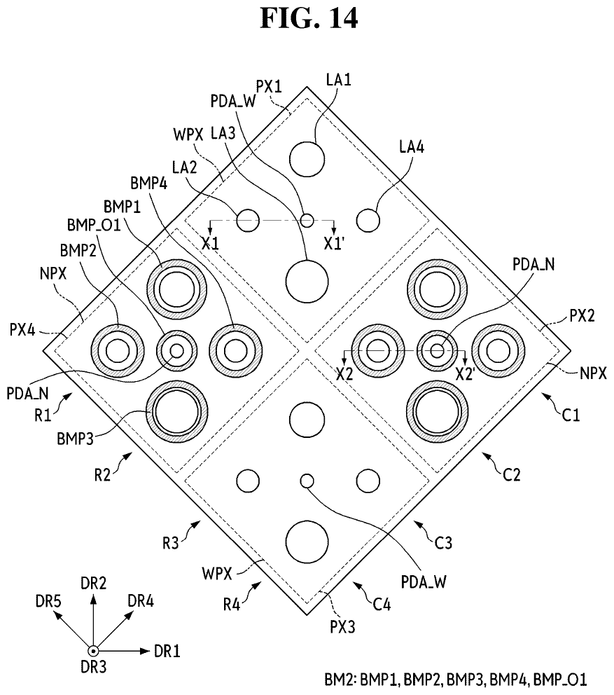

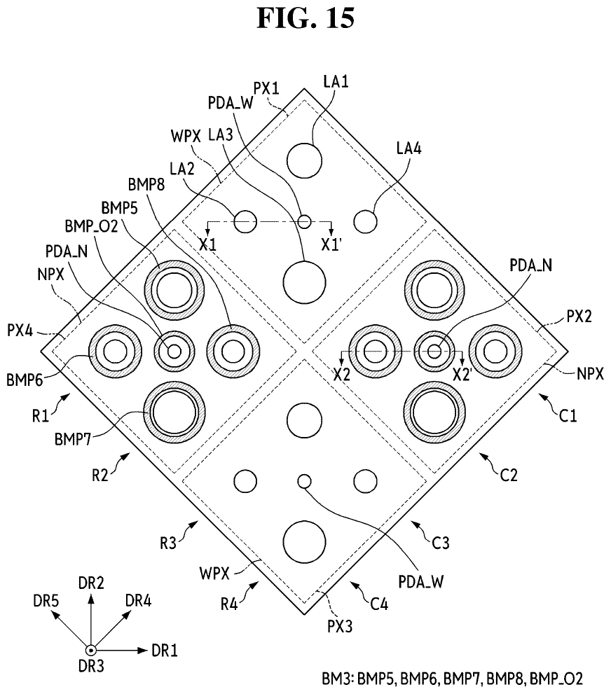

The distinction between the first type pixel and the second type pixel may be based on whether light blocking patterns of a second light blocking layer BM2 (see FIG. 14) and a third light blocking layer BM3 (see FIG. 15) to be described later are disposed in those pixels. For example, the light blocking patterns of the second light blocking layer BM2 (see FIG. 14) and the third light blocking layer BM3 (see FIG. 15) may not be disposed in the first light emitting pixel PX1 and the third light emitting pixel PX3, which are the first type pixels, whereas they may be disposed in the second light emitting pixel PX2 and the fourth light emitting pixel PX4, which are the second type pixels.

The display device 10 according to some example embodiments may include the first type pixel and the second type pixel, thereby allowing side visibility to be adjusted according to the emission mode. The light blocking patterns of the second light blocking layer BM2 (see FIG. 14) and the third light blocking layer BM3 (see FIG. 15) may block light from the emission area LA depending on the viewing angle from which the display device 10 is viewed. For example, the light blocking patterns of the second light blocking layer BM2 (see FIG. 14) and the third light blocking layer BM3 (see FIG. 15) may block the emission of light at a specific viewing angle.

For example, in a first emission mode (e.g., normal mode) of the display device 10, when the side visibility is not restricted, both the first type pixel and the second type pixel may emit light. For example, when all of the first to fourth light emitting pixels PX1, PX2, PX3, and PX4 emit light in the first emission mode, light emitted from at least the first light emitting pixel PX1 and the third light emitting pixel PX3 may be visually recognized by the user, regardless of which direction the user looks at the display device 10.

On the other hand, in a second emission mode (e.g., privacy mode) of the display device 10, when it is required to restrict the side visibility, only the second type pixel may emit light. For example, as shown in FIG. 11, when only the second light emitting pixel PX2 and the fourth light emitting pixel PX4 emit light in the second emission mode, light may be blocked at a specific viewing angle by the light blocking patterns of the second light blocking layer BM2 (see FIG. 14) and the third light blocking layer BM3 (see FIG. 15). Since the first light emitting pixel PX1 and the third light emitting pixel PX3 do not emit light, the image of the display device 10 in the second emission mode may be visually recognized only by the user looking from the front of the display area DA, and may not be visually recognized by the user looking at a specific viewing angle or from the side. Through this, the display device 10 may provide a privacy protection mode to the user.

Alternatively or additionally, in the display device 10, as the light blocking patterns of the second light blocking layer BM2 (see FIG. 14) and the third light blocking layer BM3 (see FIG. 15) are disposed to correspond to the emission areas LA of the second type pixel, the light blocking patterns of the second light blocking layer BM2 and the third light blocking layer BM3 may be disposed not to invade other adjacent pixels, e.g., the first type pixel, and thus may not cover the emission area LA of the first type pixel in the first emission mode. For example, in the display device 10, the arrangement of the pixel structure may be freely designed even in the implementation of a high-resolution display device.

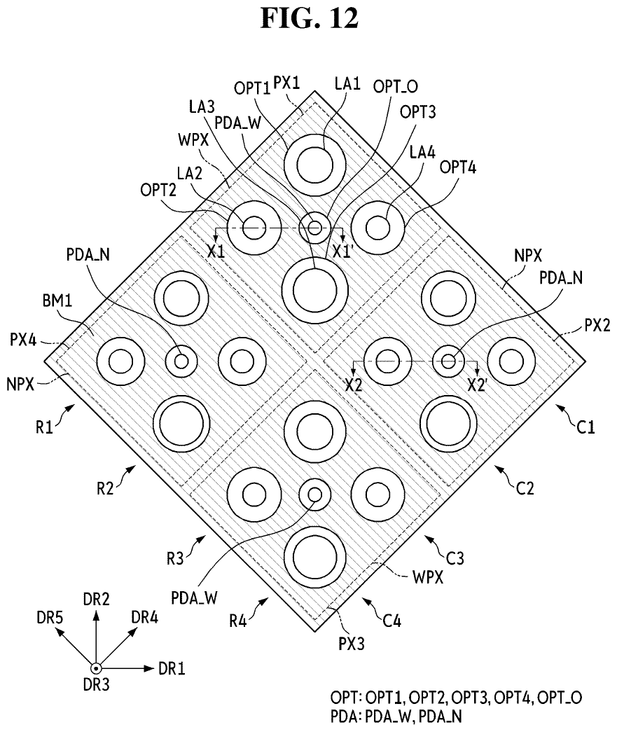

FIG. 12 is a plan view illustrating an emission area, a sensing area, and a first light blocking layer in a display device according to some example embodiments.

Referring to FIG. 12 in addition to FIGS. 7, 9, and 11, the display device 10 may include a first light blocking layer BM1. The first light blocking layer BM1 may be disposed above the emission areas LA. The first light blocking layer BM1 may be disposed over the entire display area DA. The first light blocking layer BM1 may include a plurality of holes OPT disposed to respectively correspond to the emission area LA and the sensing area PDA. The plurality of holes OPT of the first light blocking layer BM1 may be disposed to respectively correspond to the plurality of openings of the pixel defining film PDL. The first light blocking layer BM1 may cover the display area DA except for an area where the plurality of holes OPT are disposed in the display area DA. The plurality of holes OPT of the first light blocking layer BM1 may be regions through which light emitted from the light emitting element ED disposed in each emission area LA exits, and regions through which light to be collected by the light receiving element PD disposed in each sensing area PDA is incident.

The plurality of holes OPT may include a first hole OPT1 overlapping the first emission area LA1, a second hole OPT2 overlapping the second emission area LA2, a third hole OPT3 overlapping the third emission area LA3, a fourth hole OPT4 overlapping the fourth emission area LA4, and a fifth hole OPT_O overlapping the sensing area PDA.

The area of each of the plurality of holes OPT in plan view may be larger than the area of each of the emission area LA and the sensing area PDA in plan view. For example, the first hole OPT1 may have an area larger than the first emission area LA1 in plan view, the second hole OPT2 may have an area larger than the second emission area LA2 in plan view, the third hole OPT3 may have an area larger than the third emission area LA3 in plan view, the fourth hole OPT4 may have an area larger than the fourth emission area LA4 in plan view, and the fifth hole OPT_O may have an area larger than the sensing area PDA in plan view.

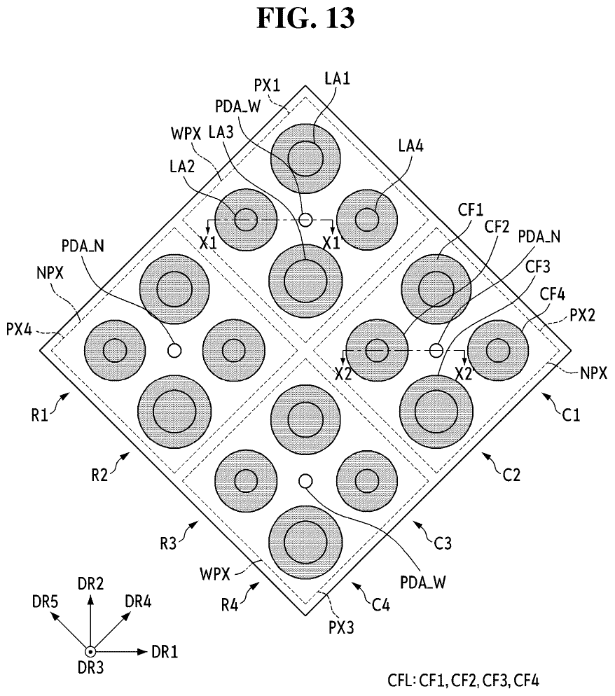

FIG. 13 is a plan view illustrating an emission area, a sensing area, and a color filter layer in a display device according to some example embodiments.

Referring to FIG. 13 in addition to FIGS. 7, 9, 11, and 12, the display device 10 may include the color filter layer CFL. The color filter layer CFL may be disposed on the first light blocking layer BM1. The color filter layer CFL may include the plurality of color filters CF1, CF2, CF3, and CF4. The plurality of color filters CF1, CF2, CF3, and CF4 may include a first color filter CF1, a second color filter CF2, a third color filter CF3, and a fourth color filter CF4.

The plurality of color filters CF1, CF2, CF3, and CF4 may be disposed to correspond to the plurality of emission areas LA, respectively. The plurality of color filters CF1, CF2, CF3, and CF4 may overlap the plurality of emission areas LA, respectively. For example, the first color filter CF1 may overlap the first emission area LA1, the second color filter CF2 may overlap the second emission area LA2, the third color filter CF3 may overlap the third emission area LA3, and the fourth color filter CF4 may overlap the fourth emission area LA4.

The plurality of color filters CF1, CF2, CF3, and CF4 may include a colorant such as a dye or a pigment that absorbs light in a wavelength band other than a specific wavelength band, and may be disposed to correspond to the color of the light emitted from the light emitting element including the emission areas LA. For example, the first color filter CF1 may be a red color filter that is disposed to overlap the first emission area LA1 and transmits only the red first light. The second color filter CF2 may be a green color filter that is disposed to overlap the second emission area LA2 and transmits only the green second light, the third color filter CF3 may be a blue color filter that is disposed to overlap the third emission area LA3 and transmits only the blue third light, and the fourth color filter CF4 may be a green color filter that is disposed to overlap the fourth emission area LA4 and transmits only the green second light.

In some example embodiments, each of the plurality of color filters CF1, CF2, CF3, and CF4 may not be disposed above the sensing area PDA. For example, each of the plurality of color filters CF1, CF2, CF3, and CF4 may not overlap the sensing area PDA.

The plurality of color filters CF1, CF2, CF3, and CF4 may be disposed to correspond to the plurality of holes OPT of the first light blocking layer BM1. The plurality of color filters CF1, CF2, CF3, and CF4 may overlap the plurality of holes OPT of the first light blocking layer BM1. For example, the first color filter CF1 may overlap the first hole OPT1, the second color filter CF2 may overlap the second hole OPT2, the third color filter CF3 may overlap the third hole OPT3, and the fourth color filter CF4 may overlap the fourth hole OPT4.

The plurality of color filters CF1, CF2, CF3, and CF4 may have an area larger than the plurality of holes OPT of the first light blocking layer BM1, and may completely cover light exit regions formed by the plurality of holes OPT of the first light blocking layer BM1. The plurality of color filters CF1, CF2, CF3, and CF4 may completely overlap the plurality of holes OPT of the first light blocking layer BM1. However, in some embodiments, the color filters CF1, CF2, CF3, and CF4 may be omitted.

Similarly to the arrangement of the emission areas LA, the color filters CF1, CF2, CF3, and CF4 may be disposed in a PenTile™ type, for example, a diamond PenTile™ type. For example, the first color filter CF1 and the third color filter CF3 may be alternately disposed in the first direction DR1 and the second direction DR2. The second color filter CF2 and the fourth color filter CF4 may be arranged in the first direction DR1 and the second direction DR2, and the second color filter CF2 and the adjacent first color filter CF1 and the adjacent third color filter CF3 may be arranged in the fourth direction DR4 or the fifth direction DR5. The second color filter CF2 and the fourth color filter CF4 may be repeatedly arranged along the first direction DR1 and the second direction DR2, and the second color filter CF2 and the first color filter CF1, or the fourth color filter CF4 and the third color filter CF3 may be alternately arranged along the fourth direction DR4.

According to some example embodiments, the plurality of color filters CF1, CF2, CF3, and CF4 may have different sizes or areas in plan view. As described above, the sizes of areas of the plurality of emission areas LA may be different from each other, so that the planar sizes or areas of the plurality of color filters CF1, CF2, CF3, and CF4 may also be different from each other.

The shape of the plurality of color filters CF1, CF2, CF3, and CF4 in plan view may be a circular shape similar to the shape of the emission areas LA. However, example embodiments are not limited thereto, and the color filters CF1, CF2, CF3, and CF4 may have a rectangular or rhombic shape in plan view.

FIG. 14 is a plan view illustrating an emission area, a sensing area, and a second light blocking layer in a display device according to some example embodiments. FIG. 15 is a plan view illustrating an emission area, a sensing area, and a third light blocking layer in a display device according to some example embodiments.

Referring to FIGS. 14 and 15 in addition to FIGS. 7, 9, and 11 to 13, the display device 10 may include the second light blocking layer BM2 and the third light blocking layer BM3. The second light blocking layer BM2 may be disposed on the color filter layer CFL. The third light blocking layer BM3 may be disposed above the second light blocking layer BM2.

The second light blocking layer BM2 and the third light blocking layer BM3 may include a plurality of light blocking patterns BMP1 to BMP8. For example, the second light blocking layer BM2 may include a first light blocking pattern BMP1, a second light blocking pattern BMP2, a third light blocking pattern BMP3, and a fourth light blocking pattern BMP4. The third light blocking layer BM3 may include a fifth light blocking pattern BMP5, a sixth light blocking pattern BMP6, a seventh light blocking pattern BMP7, and an eighth light blocking pattern BMP8.

The plurality of light blocking patterns BMP1 to BMP8 may be disposed above some of the plurality of light emitting pixels PX of the display area DA. The plurality of light blocking patterns BMP1 to BMP8 may be disposed above the privacy mode pixel NPX, which is the second type pixel, among the plurality of light emitting pixels PX. For example, the plurality of light blocking patterns BMP1 to BMP8 may be disposed above the second light emitting pixel PX2 and the fourth light emitting pixel PX4.

The plurality of light blocking patterns BMP1 to BMP8 may not overlap the first type pixel including the first light emitting pixel PX1 and the third light emitting pixel PX3, but may overlap the second type pixel including the second light emitting pixel PX2 and the fourth light emitting pixel PX4.

The plurality of light blocking patterns BMP1 to BMP8 may be disposed to correspond to the plurality of emission areas LA in the privacy mode pixel NPX, which is the second type pixel. For example, the first light blocking pattern BMP1 may be disposed to surround the first emission area LA1 of the privacy mode pixel NPX, the second light blocking pattern BMP2 may be disposed to surround the second emission area LA2 of the privacy mode pixel NPX, the third light blocking pattern BMP3 may be disposed to surround the third emission area LA3 of the privacy mode pixel NPX, and the fourth light blocking pattern BMP4 may be disposed to surround the fourth emission area LA4 of the privacy mode pixel NPX.

The plurality of light blocking patterns BMP1 to BMP8 may each have a ring shape or a donut shape surrounding its corresponding emission area LA. For example, the plurality of light blocking patterns BMP1 to BMP8 may include a plurality of transmission holes that overlap the plurality of emission areas LA. The area of the transmission holes of the plurality of light blocking patterns BMP1 to BMP8 in plan view may be larger than the area of the corresponding emission areas LA in plan view. For example, the inner side surfaces of the plurality of light blocking patterns BMP1 to BMP8 may be spaced apart from the boundaries of the plurality of openings of the pixel defining film PDL in plan view.

In some example embodiments, the plurality of light blocking patterns may further include a ninth light blocking pattern BMP_O1 and a tenth light blocking pattern BMP_O2. The ninth light blocking pattern BMP_O1 may be included in the second light blocking layer BM2, and the tenth light blocking pattern BMP_O2 may be included in the third light blocking layer BM3.

The ninth light blocking pattern BMP_O1 and the tenth light blocking pattern BMP_O2 may each be disposed to correspond to the sensing area PDA that overlaps the privacy mode pixel NPX, which is the second type pixel. For example, the ninth light blocking pattern BMP_O1 and the tenth light blocking pattern BMP_O2 may each be disposed to surround the second sensing area PDA_N of the privacy mode pixel NPX.

The ninth light blocking pattern BMP_O1 and the tenth light blocking pattern BMP_O2 may each have a ring shape or a donut shape surrounding its corresponding sensing area PDA. For example, the ninth light blocking pattern BMP_O1 and the tenth light blocking pattern BMP_O2 may include a plurality of transmission holes overlapping the plurality of sensing areas PDA. The area of the transmission holes of the ninth light blocking pattern BMP_O1 and the tenth light blocking pattern BMP_O2 in plan view may be larger than the area of the corresponding sensing areas PDA in plan view. For example, the inner side surfaces of the ninth light blocking pattern BMP_O1 and the tenth light blocking pattern BMP_O2 may be spaced apart from the boundaries of the plurality of openings of the pixel defining film PDL in plan view.

Each of the ninth light blocking pattern BMP_O1 and the tenth light blocking pattern BMP_O2 may not be disposed above the first sensing area PDA_W.

The display device 10 according to some example embodiments may include the plurality of light blocking patterns BMP1 to BMP8 of the second light blocking layer BM2 and the third light blocking layer BM3, which surround the plurality of emission areas LA, thereby controlling visibility at a specific viewing angle and providing a privacy protection mode to the user.

In addition, the display device 10 according to some example embodiments may include the plurality of light blocking patterns BMP_O1 and BMP_O2 of the second light blocking layer BM2 and the third light blocking layer BM3, which surround the plurality of sensing areas PDA, thereby collecting data in a narrow range to improve the accuracy of sensing data.

In some example embodiments, the ninth light blocking pattern BMP_O1 and the tenth light blocking pattern BMP_O2 may be omitted. In this case, the amount of light incident on the light receiving element PD may increase, thereby improving the sensing accuracy of the light receiving element PD.

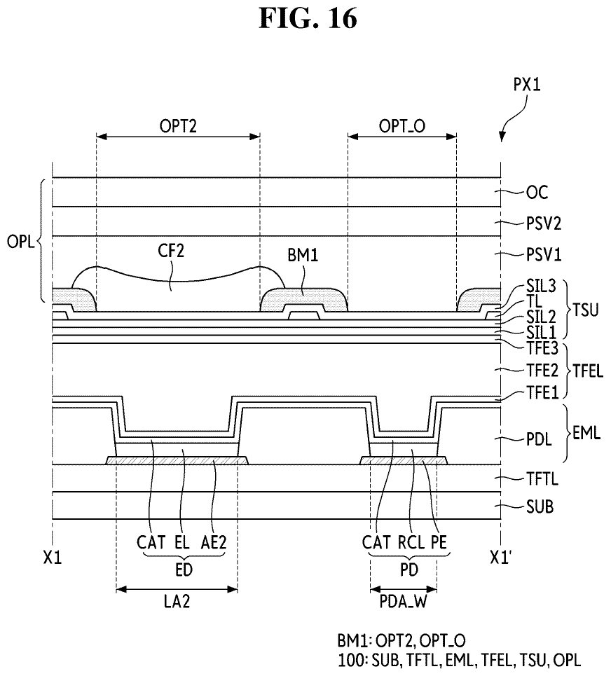

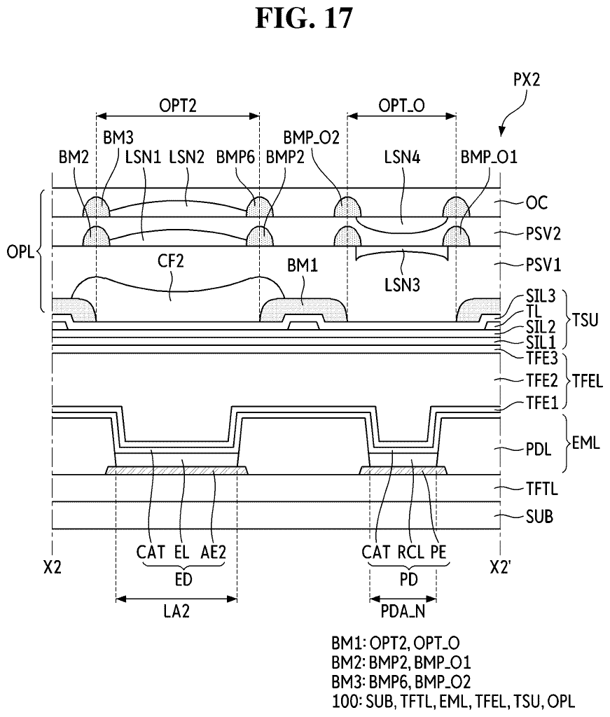

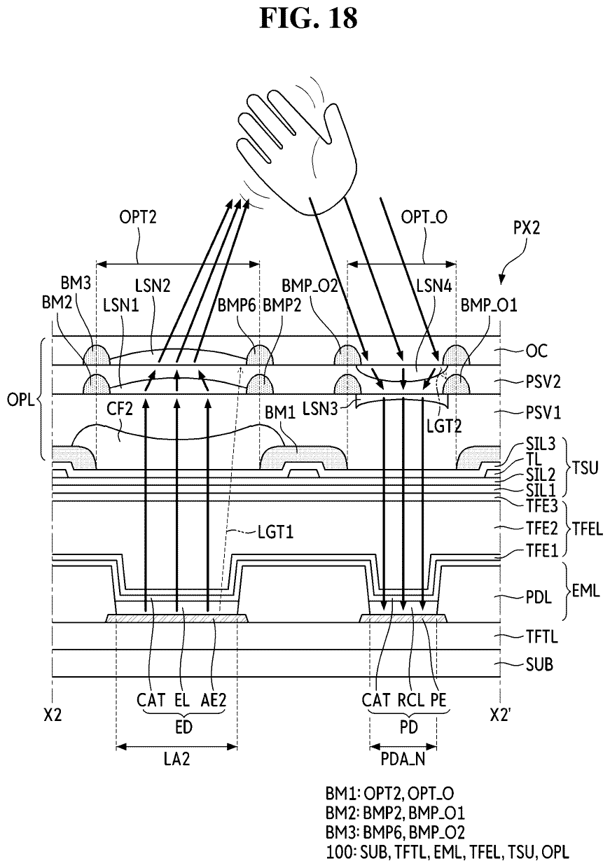

FIG. 16 is a cross-sectional view taken along line X1-X1′. FIG. 17 is a cross-sectional view taken along line X2-X2′. FIG. 18 is a cross-sectional view illustrating a sensing process of a display device according to some example embodiments. FIG. 16 illustrates a cross-section traversing the second emission area LA2 and the first sensing area PDA_W in the first light emitting pixel PX1, which is the first type pixel. FIG. 17 illustrates a cross-section traversing the second emission area LA2 and the second sensing area PDA_N in the second light emitting pixel PX2, which is the second type pixel.

Referring to FIGS. 16 to 18 in addition to FIGS. 7, 9, and 10 to 15, the display panel 100 of the display device 10 may include the substrate SUB, the transistor layer TFTL, the element layer EML, the encapsulation layer TFEL, the touch sensing layer TSU, and an optical layer OPL. The optical layer OPL may include the first light blocking layer BM1, the color filter layer CFL, a first passivation layer PSV1, the second light blocking layer BM2, a second passivation layer PSV2, the third light blocking layer BM3, and an overcoat layer OC.

Descriptions of the substrate SUB, the transistor layer TFTL, and the element layer EML have been previously provided with reference to FIGS. 7 and 9 and are therefore omitted here.

The encapsulation layer TFEL may be disposed on the common electrode CAT to cover the plurality of light emitting elements ED and the plurality of light receiving elements PD. The encapsulation layer TFEL may include at least one inorganic film to prevent oxygen or moisture from penetrating into the element layer EML. The encapsulation layer TFEL may include at least one organic film to protect the element layer EML from foreign matters such as dust.

In some example embodiments, the encapsulation layer TFEL may include a first encapsulation layer TFE1, a second encapsulation layer TFE2, and a third encapsulation layer TFE3. The first encapsulation layer TFE1 and the third encapsulation layer TFE3 may be inorganic encapsulation layers, and the second encapsulation layer TFE2 disposed between the first encapsulation layer TFE1 and the third encapsulation layer TFE3 may be an organic encapsulation layer.

Each of the first encapsulation layer TFE1 and the third encapsulation layer TFE3 may include one or more inorganic insulating materials. The inorganic insulating material may include aluminum oxide, titanium oxide, tantalum oxide, hafnium oxide, zinc oxide, silicon oxide, silicon nitride, and/or silicon oxynitride.

The second encapsulation layer TFE2 may include a polymer-based material. Examples of the polymer-based material may include acrylic resin, epoxy resin, polyimide, polyethylene and the like. For example, the second encapsulation layer TFE2 may include an acrylic resin, for example, polymethyl methacrylate, polyacrylic acid, or the like. The second encapsulation layer TFE2 may be formed by curing a monomer or applying a polymer.

The touch sensing layer TSU may be disposed on the encapsulation layer TFEL. The touch sensing layer TSU may include a first touch insulating layer SIL1, a second touch insulating layer SIL2, a touch electrode TL, and a third touch insulating layer SIL3.

The first touch insulating layer SIL1 may be disposed on the encapsulation layer TFEL. The first touch insulating layer SIL1 may have an insulating and optical function. The first touch insulating layer SIL1 may include at least one inorganic film. Optionally, the first touch insulating layer SIL1 may be omitted.

The second touch insulating layer SIL2 may cover the first touch insulating layer SIL1. Although not illustrated in the drawings, a touch electrode of another layer may be further disposed on the first touch insulating layer SIL1, and the second touch insulating layer SIL2 may cover the touch electrode TL. The second touch insulating layer SIL2 may have an insulating and optical function. For example, the second touch insulating layer SIL2 may be an inorganic film containing at least one of a silicon nitride layer, a silicon oxynitride layer, a silicon oxide layer, a titanium oxide layer, or an aluminum oxide layer.

A part of the touch electrode TL may be disposed on the second touch insulating layer SIL2. Each of the touch electrodes TL may not overlap the light emitting element ED and the light receiving element PD. The touch electrode TL may be formed as a single layer containing one or more of molybdenum (Mo), titanium (Ti), copper (Cu), aluminum (Al), or indium tin oxide (ITO), or may be formed to have a stacked structure (Ti/Al/Ti) of aluminum and titanium, a stacked structure (ITO/Al/ITO) of aluminum and ITO, an Ag—Pd—Cu (APC) alloy, or a stacked structure (ITO/APC/ITO) of APC alloy and ITO.

The touch electrode TL of the touch sensing layer TSU may have a constant line width and may be disposed to overlap the first light blocking layer BM1, which will be described later. The first light blocking layer BM1 may have a width sufficient to completely cover the touch electrode TL, and a gap between an edge of the first light blocking layer BM1 and the touch electrode TL may be defined. In some example embodiments, the line width of the touch electrode TL may be in a range of 4 μm to 6 μm, and the gap between the touch electrode TL and the edge of the first light blocking layer BM1 may be in a range of 5 μm to 7 μm, but example embodiments are not limited thereto. The touch electrode TL may be disposed such that its center is substantially aligned with the center of the first light blocking layer BM1, and the gap from both sides of the touch electrode TL to the edge of the first light blocking layer BM1 may be substantially constant.

The third touch insulating layer SIL3 may cover the touch electrode TL and the second touch insulating layer SIL2. The third touch insulating layer SIL3 may have an insulating and optical function. The third touch insulating layer SIL3 may be made of the material exemplified in association with the second touch insulating layer SIL2.

The first light blocking layer BM1 may be disposed on the touch sensing layer TSU. The first light blocking layer BM1 may include a light absorbing material. For example, the first light blocking layer BM1 may include an inorganic black pigment or an organic black pigment. The inorganic black pigment may be carbon black, and the organic black pigment may include at least one of lactam black, perylene black, or aniline black, but they are not limited thereto.

The first light blocking layer BM1 may be disposed to cover the conductive line of the touch electrode TL. The first light blocking layer BM1 may include the plurality of holes OPT2 and OPT_O disposed to overlap the light emitting element ED and the light receiving element PD, respectively. For example, the second hole OPT2 may be disposed to overlap the second emission area LA2, and the fifth hole OPT_O may be disposed to overlap the second sensing area PDA_N.

The areas and/or sizes of the holes OPT2 and OPT_O may be larger than the areas or sizes of the second emission area LA2 and the second sensing area PDA_N, respectively. In addition, the areas and/or sizes of the holes OPT2 and OPT_O may be formed larger than those of the openings of the pixel defining film PDL. However, example embodiments are not limited thereto.

The color filter layer CFL may be disposed on the first light blocking layer BM1. The second color filter CF2 of the color filter layer CFL may be disposed on the first light blocking layer BM1. The second color filter CF2 may be disposed to correspond to the second emission area LA2 and the second hole OPT2 of the first light blocking layer BM1. The second color filter CF2 may have a width larger than the second hole OPT2 of the first light blocking layer BM1, and may be directly disposed, at least partially, on the first light blocking layer BM1.

In some embodiments, the color filter of the color filter layer CFL may not be disposed above the second sensing area PDA_N. The color filter of the color filter layer CFL may not be disposed above the fifth hole OPT_O of the first light blocking layer BM1.

The first passivation layer PSV1 may be disposed on the first light blocking layer BM1 and the color filter layer CFL. The first passivation layer PSV1 may be disposed over the entire display area DA to flatten the top surface of the display panel 100. The first passivation layer PSV1 may flatten the stepped portion caused by the color filter layer CFL and the first light blocking layer BM1.

The first passivation layer PSV1 may be a colorless light transmissive layer that does not have a color in a visible light band. For example, the first passivation layer PSV1 may include a colorless light transmissive organic material such as an acrylic resin, but is not limited thereto.

The second light blocking layer BM2 may be disposed on the first passivation layer PSV1. The second light blocking layer BM2 may include a light absorbing material. For example, the second light blocking layer BM2 may include an inorganic black pigment or an organic black pigment. The inorganic black pigment may be carbon black, and the organic black pigment may include at least one of lactam black, perylene black, or aniline black, but they are not limited thereto.

The second light blocking layer BM2 may not be disposed in the first type pixel (e.g., the first light emitting pixel PX1), but may be disposed only in the second type pixel (e.g., the second light emitting pixel PX2). The second light blocking layer BM2 may include the light blocking patterns BMP2 and BMP_O1 disposed to correspond to the light emitting element ED and the light receiving element PD. For example, the second light blocking pattern BMP2 may be disposed to correspond to the second emission area LA2, and the ninth light blocking pattern BMP_O1 may be disposed to correspond to the second sensing area PDA_N.

The second light blocking pattern BMP2 and the ninth light blocking pattern BMP_O1 may include transmission holes that overlap the light emitting element ED and the light receiving element PD, respectively. The areas or sizes of the transmission holes of the second light blocking pattern BMP2 and the ninth light blocking pattern BMP_O1 may be larger than the areas or sizes of the second emission area LA2 and the second sensing area PDA_N, respectively. In addition, the areas or sizes of the transmission holes may be formed larger than those of the openings of the pixel defining film PDL. However, example embodiments are not limited thereto.

The second passivation layer PSV2 may be disposed on the second light blocking layer BM2 and the first passivation layer PSV1. The second passivation layer PSV2 may be disposed over the entire display area DA to flatten the top surface of the display panel 100. The second passivation layer PSV2 may flatten the stepped portion caused by the second light blocking layer BM2.

The second passivation layer PSV2 may be a colorless light transmissive layer that does not have a color in a visible light band. For example, the second passivation layer PSV2 may include a colorless light transmissive organic material such as an acrylic resin, but is not limited thereto.

The third light blocking layer BM3 may be disposed on the second passivation layer PSV2. The third light blocking layer BM3 may include a light absorbing material. For example, the third light blocking layer BM3 may include an inorganic black pigment or an organic black pigment. The inorganic black pigment may be carbon black, and the organic black pigment may include at least one of lactam black, perylene black, or aniline black, but they are not limited thereto.

The third light blocking layer BM3 may not be disposed in the first type pixel (e.g., the first light emitting pixel PX1), but may be disposed only in the second type pixel (e.g., the second light emitting pixel PX2). The third light blocking layer BM3 may include the light blocking patterns BMP6 and BMP_O2 disposed to correspond to the light emitting element ED and the light receiving element PD. For example, the sixth light blocking pattern BMP6 may be disposed to correspond to the second emission area LA2, and the tenth light blocking pattern BMP_O2 may be disposed to correspond to the second sensing area PDA_N.

The sixth light blocking pattern BMP6 and the tenth light blocking pattern BMP_O2 may include transmission holes that overlap the light emitting element ED and the light receiving element PD, respectively. The areas or sizes of the transmission holes of the sixth light blocking pattern BMP6 and the tenth light blocking pattern BMP_O2 may be larger than the areas or sizes of the second emission area LA2 and the second sensing area PDA_N, respectively. In addition, the areas or sizes of the transmission holes may be formed larger than those of the openings of the pixel defining film PDL. However, example embodiments are not limited thereto.

The overcoat layer OC may be disposed on the third light blocking layer BM3 and the second passivation layer PSV2. The overcoat layer OC may be disposed over the entire display area DA to flatten the top surface of the display panel 100. The overcoat layer OC may flatten the stepped portion caused by the third light blocking layer BM3.

The overcoat layer OC may be or may include, or be included in, a colorless light transmissive layer that does not have a color in a visible light band. For example, the overcoat layer OC may include a colorless light transmissive organic material such as an acrylic resin, but is not limited thereto.

The display device 10 according to some example embodiments may further include a lens unit LSN1, LSN2, LSN3, and LSN4. The lens unit LSN1, LSN2, LSN3, and LSN4 may include a first lens LSN1, a second lens LSN2, a third lens LSN3, and a fourth lens LSN4.

The first lens LSN1 and the third lens LSN3 may be disposed between the first passivation layer PSV1 and the second passivation layer PSV2. The second lens LSN2 and the fourth lens LSN4 may be disposed between the second passivation layer PSV2 and the overcoat layer OC.

The first lens LSN1 may be disposed in the transmission hole of the second light blocking pattern BMP2. The second lens LSN2 may be disposed in the transmission hole of the sixth light blocking pattern BMP6. The third lens LSN3 may be disposed in the transmission hole of the ninth light blocking pattern BMP_O1. The fourth lens LSN4 may be disposed in the transmission hole of the tenth light blocking pattern BMP_O2.

The first lens LSN1 and the second lens LSN2 may be disposed to overlap the second hole OPT2 of the first light blocking layer BM1. The first lens LSN1 and the second lens LSN2 may be disposed to overlap the second emission area LA2. The third lens LSN3 and the fourth lens LSN4 may be disposed to overlap the fifth hole OPT_O of the first light blocking layer BM1. The third lens LSN3 and the fourth lens LSN4 may be disposed to overlap the second sensing area PDA_N.

In some example embodiments, even when the display device 10 does not include the ninth light blocking pattern BMP_O1 and the tenth light blocking pattern BMP_O2, the display device 10 may include the third lens LSN3 and the fourth lens LSN4. In this case, the third lens LSN3 and the fourth lens LSN4 are not disposed in the transmission holes of the ninth light blocking pattern BMP_O1 and the tenth light blocking pattern BMP_O2, but may still be disposed to overlap the fifth hole OPT_O and the second sensing area PDA_N.

In FIG. 17, the first lens LSN1 and the second lens LSN2 are exemplarily shown as being disposed above the second emission area LA2, but the first lens LSN1 and the second lens LSN2 may also be similarly disposed above the first emission area LA1, the third emission area LA3, and the fourth emission area LA4.

For example, the first lens LSN1 and the second lens LSN2 may also overlap the first emission area LA1, the third emission area LA3, and the fourth emission area LA4 of the privacy mode pixel NPX shown in FIG. 11. In addition, the first lens LSN1 and the second lens LSN2 may also overlap the first hole OPT1, the third hole OPT3, and the fourth hole OPT4 of the privacy mode pixel NPX shown in FIG. 12. In addition, the first lens LSN1 and the second lens LSN2 may also overlap the transmission hole of the first light blocking pattern BMP1, the transmission hole of the third light blocking pattern BMP3, and the transmission hole of the fourth light blocking pattern BMP4 of the privacy mode pixel NPX shown in FIG. 14. In addition, the first lens LSN1 and the second lens LSN2 may also overlap the transmission hole of the fifth light blocking pattern BMP5, the transmission hole of the seventh light blocking pattern BMP7, and the transmission hole of the eighth light blocking pattern BMP8 of the privacy mode pixel NPX shown in FIG. 15.

In some embodiments, the first lens LSN1, the second lens LSN2, and the fourth lens LSN4 may include condensing lenses. For example, the first lens LSN1, the second lens LSN2, and the fourth lens LSN4 may include convex lenses. The third lens LSN3 may include a collimating lens. For example, the third lens LSN3 may include a concave lens.

When the first lens LSN1 and the second lens LSN2 include convex lenses, they may have convex surfaces in the opposite direction to the side where the light emitting element ED is located. When the fourth lens LSN4 includes a convex lens, it may have a convex surface toward the side where the light receiving element PD is located. When the third lens LSN3 includes a concave lens, it may have a concave surface with respect to the side where the light receiving element PD is located.

The display device 10 according to some example embodiments may include the lens unit LSN1, LSN2, LSN3, and LSN4, thereby increasing the amount of light received by the light receiving element PD and improving the sensing accuracy of the light receiving element PD.

For example, as shown in FIG. 18, light emitted from the light emitting element ED may be collected by passing through the first lens LSN1 and the second lens LSN2. Accordingly, the light may be reflected from a narrow range of the object, thereby improving the quality of the sensing data and the sensing accuracy of the light receiving element PD. In addition, a portion of light LGT1 that should be blocked by the second light blocking layer BM2 and the third light blocking layer BM3 may be collected by the first lens LSN1 and the second lens LSN2 and be able to exit to the outside, thereby improving the light emission efficiency. Accordingly, the amount of light received by the light receiving element PD may be improved.

Meanwhile, the light reflected from the object may be collected by passing through the fourth lens LSN4. Accordingly, a portion of light LGT2 that should be blocked by the second light blocking layer BM2 and the third light blocking layer BM3 may be collected by the fourth lens LNS4 and incident into the display device 10. As a result, the amount of light received by the light receiving element PD may be improved.

The light collected by the fourth lens LSN4 may pass through the third lens LSN3 and be converted into parallel light. Accordingly, light may be uniformly incident on the entire area of the light receiving element PD, e.g., the entire second sensing area PDA_N. Therefore, the sensing accuracy of the light receiving element PD may be improved.

In some example embodiments, the refractive indices of the lens unit LSN1, LSN2, LSN3, and LSN4 may be greater than or equal to the refractive indices of the first passivation layer PSV1, the second passivation layer PSV2, and the overcoat layer OC. Accordingly, the light collecting capability of the lens unit LSN1, LSN2, LSN3, and LSN4 may be further improved.

In some example embodiments, the lens unit LSN1, LSN2, LSN3, and LSN4 may contain at least one of silicon, polymethyl methacrylate (PMMA), or plastic to have a refractive index greater than those of the first passivation layer PSV1, the second passivation layer PSV2, and the overcoat layer OC.

In some example embodiments, the refractive index of the overcoat layer OC may be greater than or equal to the refractive index of the second passivation layer PSV2, and the refractive index of the second passivation layer PSV2 may be greater than or equal to the refractive index of the first passivation layer PSV1. Accordingly, when the light emitted from the light emitting element ED exits to the outside, the degree of light collection may be further increased.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

In concluding the detailed description, those of ordinary skill in the art will appreciate that many variations and modifications can be made to example embodiments without substantially departing from the principles of inventive concepts. Therefore, some example embodiments are used in a generic and descriptive sense only and not for purposes of limitation. Additionally, example embodiments are not necessarily mutually exclusive with one another. For example, some example embodiments may include one or more features described with reference to one or more figures, and may also include one or more other features described with reference to one or more other figures.

What is claimed is:

1. A display device comprising:
a substrate;
an element layer on the substrate and comprising a light emitting element and a light receiving element spaced apart from each other;
a first light blocking layer on the element layer and defining a first hole overlapping the light emitting element and a second hole overlapping the light receiving element;
a second light blocking layer on the first light blocking layer and defining a first transmission hole overlapping the first hole and a second transmission hole overlapping the second hole;
a third light blocking layer on the second light blocking layer and defining a third transmission hole overlapping the first transmission hole and a fourth transmission hole overlapping the second transmission hole; and
a lens unit comprising a first lens in the first transmission hole, a second lens in the second transmission hole, a third lens in the third transmission hole, and a fourth lens in the fourth transmission hole,
wherein the first lens, the third lens, and the fourth lens comprise condensing lenses, and the second lens comprises a collimating lens.

2. The display device of claim 1, wherein the first lens, the third lens, and the fourth lens comprise convex lenses.

3. The display device of claim 2, wherein the first lens and the third lens have convex surfaces in an opposite direction to a side where the light emitting element is located.

4. The display device of claim 2, wherein the fourth lens has a convex surface toward a side where the light emitting element is located.

5. The display device of claim 1, wherein the third lens comprises a concave lens.

6. The display device of claim 5, wherein the third lens has a concave surface with respect to a side where the light receiving element is located.

7. The display device of claim 1, further comprising:
a first passivation layer between the first light blocking layer and the second light blocking layer;
a second passivation layer between the second light blocking layer and the third light blocking layer; and
an overcoat layer on the third light blocking layer.

8. The display device of claim 7, wherein a refractive index of the lens unit is greater than or equal to those of the first passivation layer, the second passivation layer, and the overcoat layer.

9. The display device of claim 7, wherein a refractive index of the overcoat layer is greater than or equal to a refractive index of the the second passivation layer, and the refractive index of the second passivation layer is greater than or equal to a refractive index of the first passivation layer.

10. The display device of claim 7, wherein the first passivation layer, the second passivation layer, and the overcoat layer contain a same or different organic materials.

11. The display device of claim 1, wherein the lens unit contains at least one of silicon, polymethyl methacrylate, or plastic.

12. The display device of claim 1, further comprising a color filter overlapping the first hole.

13. The display device of claim 12, wherein the color filter does not overlap the second hole.

14. A display device comprising:
a substrate comprising a display area in which a first pixel and a second pixel are arranged;
a light emitting element and a light receiving element spaced apart from each other in the display area;
a first light blocking layer defining a first hole in the first pixel and overlapping the light emitting element, a second hole in the first pixel and overlapping the light receiving element, a third hole in the second pixel and overlapping the light emitting element, and a fourth hole in the second pixel and overlapping the light receiving element;
a second light blocking layer defining a first transmission hole in the second pixel and overlapping the third hole and a second transmission hole in the second pixel and overlapping the fourth hole;
a third light blocking layer defining a third transmission hole overlapping the first transmission hole and a fourth transmission hole overlapping the second transmission hole; and
a lens unit comprising a first lens in the first transmission hole, a second lens in the second transmission hole, a third lens in the third transmission hole, and a fourth lens in the fourth transmission hole,
wherein the first lens, the third lens, and the fourth lens comprise condensing lenses, and the second lens comprises a collimating lens.

15. The display device of claim 14, wherein the first lens, the third lens, and the fourth lens comprise convex lenses.

16. The display device of claim 14, wherein the third lens comprises a concave lens.

17. The display device of claim 14, wherein the second light blocking layer and the third light blocking layer are not disposed in the first pixel.

18. The display device of claim 14, wherein the lens unit is not in the first pixel.

19. The display device of claim 14, wherein the first to fourth transmission holes do not overlap the first hole and the second hole.

20. An electronic device comprising the display device of claim 1.
